(19) United States
(12) Patent Application Publication
(10) Pub. No.: US 2023/0017800 A1
(43) Pub. Date: Jan. 19, 2023

(54) SEMICONDUCTOR DEVICE AND METHOD FOR FABRICATING THE SAME

(71) Applicant: SK hynix Inc., Gyeonggi-do (KR)

(72) Inventor: Min Chul SUNG, Gyeonggi-do (KR)

(21) Appl. No.: 17/717,959

(22) Filed: Apr. 11, 2022

(30) Foreign Application Priority Data
Jul. 13, 2021 (KR) 10-2021-0091589
Oct. 29, 2021 (KR) 10-2021-0147251

(51) Int. Cl. H01L 27/108

(52) U.S. Cl. CPC H01L 27/10885; H01L 27/10888; H01L 27/10814

(57) ABSTRACT

A semiconductor device includes a plurality of bit line structures formed to be spaced apart from each other over a semiconductor substrate, a first spacer formed on both sidewalls of each of the bit line structures, a lower plug formed between the bit line structures and in contact with the semiconductor substrate, an upper plug positioned over the lower plug and having a greater line width than the lower plug, a middle plug positioned between the lower plug and the upper plug and having a smaller line width than a line width of the lower plug, and a second spacer positioned between the middle plug and the first spacer, wherein the second spacer is thicker than the first spacer.

### CROSS-REFERENCE TO RELATED APPLICATIONS

The present application claims priority of Korean Patent Application No. 10-2021-0091589, filed on Jul. 13, 2021, and 10-2021-0147251, filed on Oct. 29, 2021, which are incorporated herein by reference in their entirety.

### BACKGROUND

### 1. Field

Embodiments of the present invention relate to a semiconductor device, and more particularly, to a semiconductor device including a dual contact plug, and a method for fabricating the same.

### 2. Description of the Related Art

In a semiconductor device, a dielectric material is formed between the neighboring pattern structures. As semiconductor devices are highly integrated, the gap between the pattern structures becomes narrower, which may parasitic capacitance. The increase in the parasitic capacitance deteriorates the performance of the semiconductor devices.

### SUMMARY

Embodiments of the present invention are directed to a semiconductor device capable of decreasing parasitic capacitance, and a method for fabricating the semiconductor device.

In accordance with an embodiment of the present invention, a semiconductor device includes: a plurality of bit line structures formed to be spaced apart from each other over a semiconductor substrate; a first spacer formed on both sidewalls of each of the bit line structures; a lower plug formed between the bit line structures and in contact with the semiconductor substrate; an upper plug positioned over the lower plug and having a greater line width than the lower plug; a middle plug positioned between the lower plug and the upper plug and having a smaller line width than a line width of the lower plug; and a second spacer positioned between the middle plug and the first spacer, wherein the second spacer is thicker than the first spacer.

In accordance with another embodiment of the present invention, a method for fabricating a semiconductor device includes: forming a plurality of bit line structures over a semiconductor substrate; forming a first spacer on both sidewalls of each of the bit line structures; forming plug isolation layers and initial contact openings that are positioned between the bit line structures over the first spacer; trimming the plug isolation layers and the initial contact openings to form contact openings which are wider than the initial contact openings; forming sacrificial spacers surrounding sidewalls of the contact openings; forming lower plugs partially filling the contact openings; removing the sacrificial spacers to form air gaps surrounding the lower plugs; and forming second spacers to fill the air gaps while surrounding the lower plugs.

In accordance with another embodiment of the present invention, a method for fabricating a semiconductor device includes: forming a plurality of bit line structures over a semiconductor substrate; forming a first spacer on both sidewalls of each of the bit line structures; forming a sacrificial spacer over the first spacer; forming plug isolation layers and initial contact openings that are positioned between the bit line structures over the sacrificial spacer; forming lower plugs partially filling the initial contact openings; trimming the sacrificial spacer and the plug isolation layers to form contact openings which are wider than the initial contact openings; forming a second spacer that surrounds sidewalls of the contact openings and is thicker than the first spacer; and forming upper plugs having a greater line width than the lower plugs over the second spacer and the lower plugs.

In accordance with another embodiment of the present invention, a method for fabricating a semiconductor device includes: forming a plurality of bit line structures over a semiconductor substrate; forming a first spacer on both sidewalls of each of the bit line structures; forming a sacrificial spacer over the first spacer; forming plug isolation layers and initial contact openings positioned between the bit line structures over the sacrificial spacer; trimming the sacrificial spacer and the plug isolation layers to form contact openings which are wider than the initial contact openings; forming lower plugs partially filling the initial contact openings; removing the sacrificial spacer to form an air gap surrounding sidewalls of the lower plugs; forming a second spacer that fills the air gap and is thicker than the first spacer; and forming upper plugs having a greater line width than the lower plugs over the second spacer and the lower plugs.

In accordance with another embodiment of the present invention, a method for fabricating a semiconductor device includes: forming a plurality of bit line structures over a semiconductor substrate; forming a first spacer on both sidewalls of each of the bit line structures; forming a first sacrificial spacer over the first spacer; forming plug isolation layers and initial contact openings positioned between the bit line structures over the first sacrificial spacer; trimming the plug isolation layers to form contact openings which are wider than the initial contact openings; forming wide plugs partially filling the initial contact openings; forming a second sacrificial spacer over the wide plugs; forming narrow plugs having a smaller line width than the wide plugs over the wide plugs exposed by the second sacrificial spacer; removing the first and second sacrificial spacers to form an air gap surrounding sidewalls of the narrow plugs; forming a second spacer that fills the air gap and is thicker than the first spacer; and forming upper plugs having a greater line width than the narrow plugs over the second spacer and the narrow plugs.

In accordance with another embodiment of the present invention, a semiconductor device includes: plurality of bit line structures formed to be spaced apart from each other over a semiconductor substrate; a plurality of first spacers formed on both sidewalls of each of the bit line structures; a plurality of lower plugs formed between the plurality of bit line structures and in contact with the semiconductor substrate; a plurality of upper plugs positioned above each of the lower plugs and having a line width greater than that of the lower plugs; a plurality of middle plugs positioned between the lower plugs and the upper plugs and having a line width smaller than a line width of the lower plugs; and a plurality of second spacers positioned between the middle plugs and the first spacer, wherein the second spacers are thicker than the first spacers.

### BRIEF DESCRIPTION OF THE DRAWINGS

FIG. 1 is a plan view illustrating a semiconductor device in accordance with an embodiment of the present invention.

FIG. 2A is a cross-sectional view taken along lines A-A′ and B-B′ of FIG. 1.

FIG. 2B is an enlarged view of a storage node contact plug.

FIGS. 3 to 26 are cross-sectional views illustrating a method for fabricating a semiconductor device in accordance with an embodiment of the present invention.

FIGS. 27 to 32 are cross-sectional views illustrating a method for fabricating a semiconductor device in accordance with another embodiment of the present invention.

FIGS. 33 to 42 are cross-sectional views illustrating a method for fabricating a semiconductor device in accordance with another embodiment of the present invention.

FIGS. 43 to 48 are cross-sectional views illustrating a method for fabricating a semiconductor device in accordance with another embodiment of the present invention.

FIGS. 49A to 49D are plan views illustrating a method of forming a storage node contact plug in detail.

### DETAILED DESCRIPTION

Embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and, in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

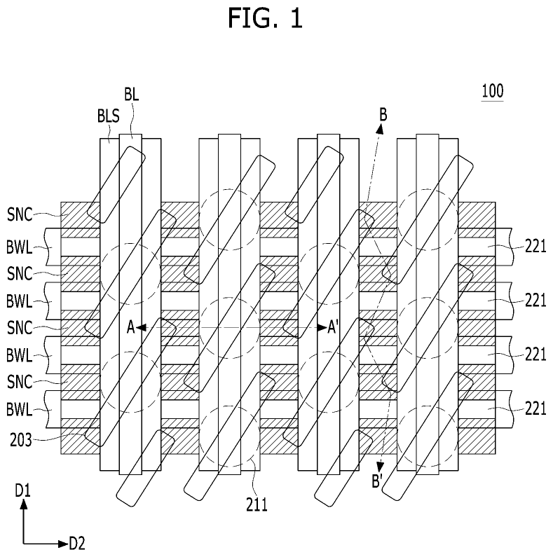

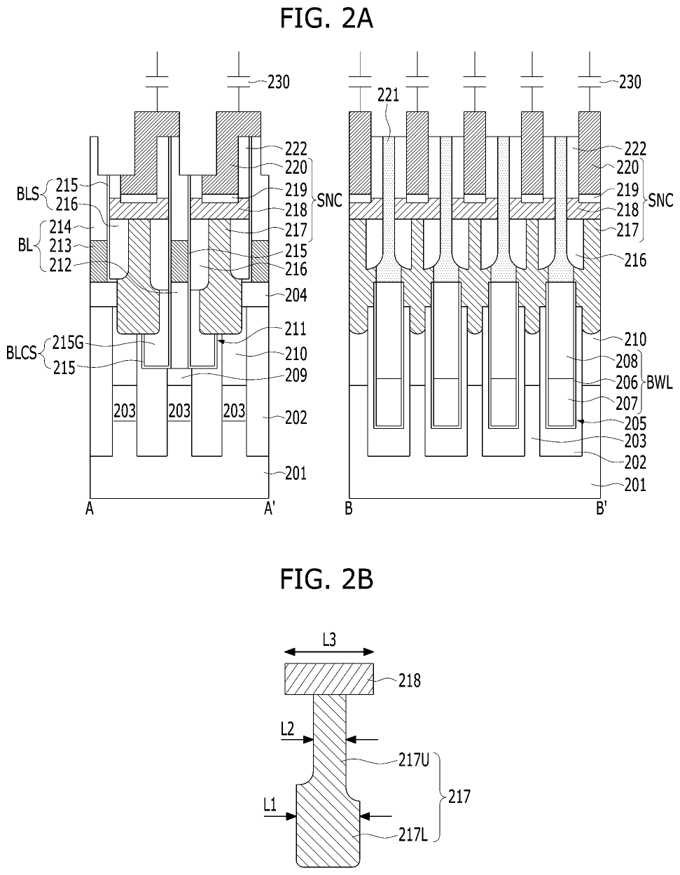

FIG. 1 is a plan view illustrating a semiconductor device in accordance with an embodiment of the present invention. FIG. 2A is a cross-sectional view taken along lines A-A′ and B-B′ of FIG. 1. FIG. 2B is an enlarged view of a storage node contact plug SNC.

The semiconductor device 100 may include a plurality of memory cells. Each of the memory cells may include a cell transistor including a buried word line 207, a bit line 213, and a memory element 230.

The semiconductor device 100 will be described in detail.

An isolation layer 202 and an active region 203 may be formed over a substrate 201. A plurality of active regions 203 may be defined by the isolation layer 202. The substrate 201 may be a material appropriate for semiconductor processing. The substrate 201 may include a semiconductor substrate. The substrate 201 may be formed of a silicon-containing material. The substrate 201 may include silicon, monocrystalline crystal silicon, polysilicon, amorphous silicon, silicon germanium, monocrystalline crystal silicon germanium, polycrystalline silicon germanium, carbon-doped silicon, a combination thereof, or a multi-layer thereof. The substrate 201 may include other semiconductor materials, such as germanium. The substrate 201 may include a III/V-group semiconductor substrate, for example, a compound semiconductor substrate such as GaAs. The substrate 201 may include a Silicon-On-Insulator (SOI) substrate. The isolation layer 202 may be formed by a Shallow Trench Isolation (STI) process.

A gate trench 205 may be formed in the substrate 201. A gate dielectric layer 206 may be formed conformally over a surface of the gate trench 205. A buried word line 207 partially filling the gate trench 205 may be formed over the gate dielectric layer 206. A gate capping layer 208 may be formed over the buried word line 207. The upper surface of the buried word line 207 may be positioned at a lower level than the surface of the substrate 201. The buried word line 207 may be a low-resistivity metal material. In the buried word line 207, titanium nitride (TiN) and tungsten (W) may be sequentially stacked. According to another embodiment of the present invention, the buried word line 207 may be formed of titanium nitride only (TiN Only). The buried word line 206 may be referred to as a ‘buried gate electrode’. The buried word line 207 may extend in a first direction Dl. The gate trench 205, the gate dielectric layer 206, the buried word line 207, and the gate capping layer 208 may be referred to as a buried word line structure BWL.

First and second impurity regions 209 and 210 may be formed in the substrate 201. The first and second impurity regions 209 and 210 may be spaced apart from each other by the gate trench 205. The first and second impurity regions 209 and 210 may be referred to as source/drain regions. The first and second impurity regions 209 and 210 may include N-type impurities, such as arsenic (As) or phosphorus (P). Accordingly, the buried word line 207 and the first and second impurity regions 209 and 210 may form a cell transistor. The cell transistor may improve a short channel effect due to the buried word line 207.

A bit line contact plug 212 may be formed over the substrate 201. The bit line contact plug 212 may be coupled to the first impurity region 209. The bit line contact plug 212 may be positioned in the inside of the bit line contact hole 211. For example, the bit line contact plug 212 may be positioned centrally inside of the bit line contact hole 211. The bit line contact hole 211 may extend to the substrate 201 through the hard mask layer 204. The hard mask layer 204 may be formed over the substrate 201. The hard mask layer 204 may include a dielectric material. The bit line contact hole 211 may expose the first impurity region 209. A lower surface of the bit line contact plug 212 may be lower than the upper surfaces of the isolation layer 202 and the active region 203. The bit line contact plug 212 may be formed of polysilicon or a metal material. A portion of the bit line contact plug 212 may have a line width which is smaller than a diameter of the bit line contact hole 211. A bit line 213 may be formed over the bit line contact plug 212. A bit line hard mask 214 may be formed over the bit line 213. The stacked structure of the bit line contact plug 212, the bit line 213, and the bit line hard mask 214 may be referred to as a bit line structure BL. The bit line 213 may have a line shape extending in a second direction D2 crossing the buried word line 207. A portion of the bit line 213 may be coupled to the bit line contact plug 212. From the perspective of an A-A′ direction, the bit line 213 and the bit line contact plug 212 may have the same line width. Accordingly, the bit line 213 may extend in the second direction D2 while covering the bit line contact plug 212. The bit line 213 may include a metal material, such as tungsten. The bit line hard mask 214 may include a dielectric material, such as silicon nitride.

A bit line contact spacer BLCS may be formed on a sidewall of the bit line contact plug 212. The bit line contact spacer BLCS may include a first spacer 215 and a gap-fill spacer 215G. A bit line spacer BLS may be formed on a sidewall of the bit line 213. The bit line spacer BLS may include a first spacer 215 and a second spacer 216. The first spacers 215 may extend to be formed on both sidewalls of the bit line contact plug 212. The first spacer 215 and the second spacer 216 may include silicon nitride. The first spacer 215 may have a thickness of approximately 10 Å or less. The first spacer 215 may include ultra-thin silicon nitride of approximately 10 Å or less. The first spacer 215 may be thinner than the second spacer 216. For example, the second spacer 216 may be twice as thick as the first spacer 215.

The bit line contact hole 211 may be filled with a bit line contact plug 212 and a bit line contact spacer BLCS.

A storage node contact plug SNC may be formed between the neighboring bit line structures BL. The storage node contact plug SNC may be coupled to the second impurity region 210. The storage node contact plug SNC may include a lower plug 217, an upper plug 218, and a landing pad 220. The lower plug 217 and the upper plug 218 may be referred to as a dual contact plug. The storage node contact plug SNC may further include an ohmic contact layer 219 between the upper plug 218 and the landing pad 220. The ohmic contact layer 219 may include a metal silicide. For example, the lower plug 217 and the upper plug 218 may include polysilicon, and the landing pad 220 may include a metal nitride, a metal material, or a combination thereof.

From the perspective of a direction parallel to the bit line structure, a plug isolation layer 221 may be formed between the neighboring storage node contact plugs SNC. The plug isolation layer 221 may be formed between the neighboring bit line structures BL. The neighboring storage node contact plugs SNC may be isolated by the plug isolation layers 221. A plurality of plug isolation layers 221 and a plurality of storage node contact plugs SNC may be alternately positioned between the neighboring bit line structures BL.

A memory element 230 may be formed over the landing pad 220. The memory element 230 may include a capacitor including a storage node. The storage node may include a pillar type. A dielectric layer and a plate node may be further formed over the storage node. The storage node may have a form of a cylinder in addition to the form of a pillar.

Referring back to FIG. 2B, the lower plug 217 of the storage node contact plug SNC may include a wide plug 217L and a narrow plug 217U. The wide plug 217L and the narrow plug 217U may be formed of the same material, but may have a discontinuous interface. In other words, the wide plug 217L and the narrow plug 217U may be formed by different processes. A line width L1 of the wide plug 217L may be greater than a line width L2 of the narrow plug 217U, and the line width L2 of the narrow plug 217U may be smaller than a line width L3 of the upper plug 218. The line width L1 of the wide plug 217L and the line width L3 of the upper plug 218 may be the same. According to another embodiment of the present invention, the line width L3 of the upper plug 218 may be larger than the line width L1 of the wide plug 217L.

Referring back to FIG. 2A, the lower plug 217 of the storage node contact plug SNC may laterally extend into the inside of the gap-fill spacer 215G. Also, the lower plug 217 may laterally extend into the inside of the second impurity region 210.

As described above, a double spacer of the first spacer 215 and the gap-fill spacer 215G may be formed between the bit line contact plug 212 and the lower plug 217 of the storage node contact plug SNC. A double spacer of the first spacer 215 and the second spacer 216 may be positioned between the bit line 213 and the storage node contact plug SNC. The second spacer 216 may be thicker than the first spacer 215.

The first spacer 215 and the gap-fill spacer 215G may include silicon nitride, and the second spacer 216 may include silicon oxide. Accordingly, a bit line spacer BLS having a nitride-oxide (NO) structure may be provided between the bit line 213 and the lower plug 217 of the storage node contact plug SNC, and a bit line contact spacer BLCS having a nitride-nitride (NN) structure may be provided between the bit line contact plug 212 and the lower plug 217 of the storage node contact plug SNC.

The plug isolation layer 221 may include silicon nitride or a low-k material. When the plug isolation layer 221 includes a low-k material, parasitic capacitance between the neighboring storage node contact plugs SNC with the plug isolation layer 221 interposed therebetween may be reduced.

According to another embodiment of the present invention, the second spacer 216 may be replaced with an air gap.

Referring to FIGS. 1 to 2B, according to the embodiment of the present embodiment, since the thickness of the silicon nitride occupied in the bit line spacer BLS, that is, the thickness of the first spacer 215, is thin (e.g., approximately 10 Å or less), it may be possible to suppress an increase in the parasitic capacitance.

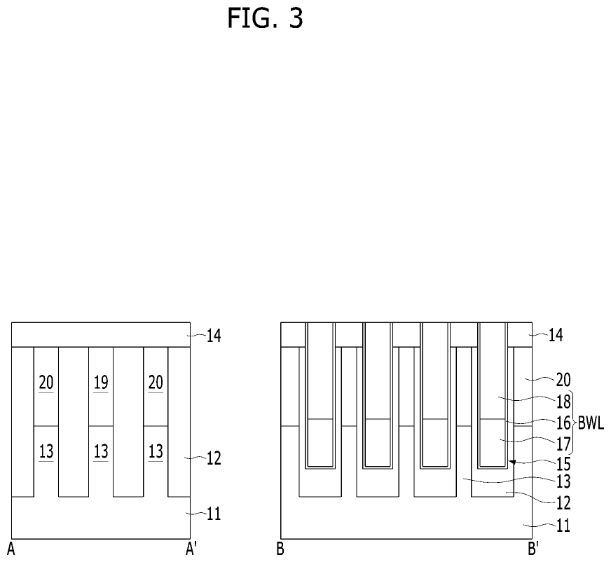

FIGS. 3 to 26 are cross-sectional views illustrating a method for fabricating a semiconductor device in accordance with an embodiment of the present invention. FIGS. 3 to 26 are cross-sectional views taken along lines A-A′ and B-B′ of FIG. 1.

Referring to FIG. 3, an isolation layer 12 may be formed over the substrate 11. A plurality of active regions 13 may be defined by the isolation layer 12. The isolation layer 12 may be formed by a Shallow Trench Isolation (STI) process. The STI process may be performed as follows. The substrate 11 may be etched to form an isolation trench (reference numeral omitted). The isolation trench may be filled with a dielectric material, and as a result the isolation layer 12 may be formed. The isolation layer 12 may include silicon oxide, silicon nitride, or a combination thereof. Chemical Vapor Deposition (CVD) or other deposition processes may be used to fill the isolation trench with a dielectric material. A planarization process such as Chemical-Mechanical Polishing (CMP) may be additionally used.

Subsequently, a buried word line structure may be formed in the substrate 11. Forming the buried word line structure may include forming a gate trench 15, a gate dielectric layer 16 covering the bottom surface and sidewalls of the gate trench 15, a buried word line 17 partially filling the gate trench 15 over the gate dielectric layer 16, and a gate capping layer 18 formed over the buried word line 17. Hence, the buried word line structure may include the gate dielectric layer 16, the buried word line 17, and the gate capping layer 18.

More specifically, the method of forming the buried word line structure may be as follows.

First, a gate trench 15 may be formed in the substrate 11. The gate trench 15 may have a line shape crossing the active regions 13 and the isolation layer 12. The gate trench 15 may be formed by forming a mask pattern over the substrate 11 and performing an etching process using the mask pattern as an etch mask. To form the gate trench 15, a hard mask layer 14 may be used as an etch barrier. The hard mask layer 14 may have a shape which is patterned by a mask pattern. The hard mask layer 14 may include silicon oxide. The hard mask layer 14 may include Tetra Ethyl Ortho Silicate (TEOS). The bottom surface of the gate trench 15 may be positioned at a higher level than the bottom surface of the isolation layer 12.

A portion of the isolation layer 12 may be recessed to protrude the active region 13 below the gate trench 15. For example, the isolation layer 12 below the gate trench 15 may be selectively recessed in the second direction D2 of FIG. 1. As a result, a fin region (reference numeral omitted) may be formed below the gate trench 15. The fin region may be a portion of a channel region.

Subsequently, a gate dielectric layer 16 may be formed over the bottom surface and sidewalls of the gate trench 15. Before the gate dielectric layer 16 is formed, etch damage on the surface of the gate trench 15 may be recovered. For example, after a sacrificial oxide is formed by thermal oxidation, the sacrificial oxide may be removed.

The gate dielectric layer 16 may be formed by a thermal oxidation process. For example, the gate dielectric layer 16 may be formed by oxidizing the bottom and sidewalls of the gate trench 15.

According to another embodiment of the present invention, the gate dielectric layer 16 may be formed by a deposition method, such as Chemical Vapor Deposition (CVD) or Atomic Layer Deposition (ALD). The gate dielectric layer 16 may include a high-k material, an oxide, nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, and a combination thereof.

According to another embodiment of the present invention, the gate dielectric layer 16 may be formed by depositing a liner polysilicon layer and then radically oxidizing the liner polysilicon layer.

According to yet another embodiment of the present invention, the gate dielectric layer 16 may be formed by forming a liner silicon nitride layer and then radically oxidizing the liner silicon nitride layer.

Subsequently, a buried word line 17 may be formed over the gate dielectric layer 16. In order to form the buried word line 17, a recessing process may be performed after a conductive layer is formed to fill the gate trench 15. The recessing process may be performed by performing an etch-back process, or by sequentially performing a chemical mechanical polishing (CMP) process and an etch-back process. The buried word line 17 may have a recessed shape that partially fills the gate trench 15. In other words, the upper surface of the buried word line 17 may be positioned at a lower level than the upper surface of the active region 13. The buried word line 17 may include a metal, a metal nitride, or a combination thereof. For example, the buried word line 17 may be formed of a titanium nitride (TiN), tungsten (W), or a stack (TiN/W) of titanium nitride/tungsten. The titanium nitride/tungsten (TiN/W) stack may have a structure in which titanium nitride is conformally formed and then the gate trench 15 is partially filled with tungsten. As for the buried word line 17, titanium nitride may be used alone, and this may be referred to as a buried word line 17 of ‘TIN Only’ structure. A double gate structure of the titanium nitride/tungsten (TiN/W) stack and a polysilicon layer may be used as the buried word line 17.

Subsequently, a gate capping layer 18 may be formed over the buried word line 17. The gate capping layer 18 may include a dielectric material. The remaining portion of the gate trench 15 over the buried word line 17 may be filled with the gate capping layer 18. The gate capping layer 18 may include silicon nitride. According to another embodiment of the present invention, the gate capping layer 18 may include silicon oxide. According to yet another embodiment of the present invention, the gate capping layer 18 may have a NON (Nitride-Oxide-Nitride) structure. The upper surface of the gate capping layer 18 may be positioned at the same level as the upper surface of the hard mask layer 14. To this end, a Chemical-Mechanical Polishing (CMP) process may be performed while the gate capping layer 18 is formed.

After the gate capping layer 18 is formed, impurity regions 19 and 20 may be formed. The impurity regions 19 and 20 may be formed by a doping process, such as implantation. The impurity regions 19 and 20 may include a first impurity region 19 and a second impurity region 20. The first and second impurity regions 19 and 20 may be doped with impurities of the same conductivity type. The first and second impurity regions 19 and 20 may have the same depth. According to another embodiment of the present invention, the first impurity region 19 may be deeper than the second impurity region 20. The first and second impurity regions 19 and 20 may be referred to as source/drain regions. The first impurity region 19 may be a region to which a bit line contact plug is to be coupled, and the second impurity region 20 may be a region to which a storage node contact plug is to be coupled. The first impurity region 19 and the second impurity region 20 may be positioned in different active regions 13. Also, the first impurity region 19 and the second impurity region 20 may be spaced apart from each other by the gate trenches 15 and positioned in the active regions 13, respectively.

A cell transistor of a memory cell may be formed by the buried word line 17, the first impurity region 19, and the second impurity region 20.

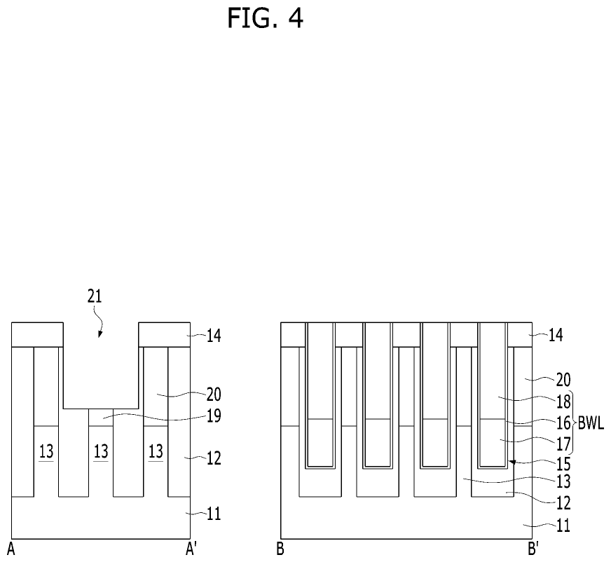

Referring to FIG. 4, a bit line contact hole 21 may be formed. The hard mask layer 14 may be etched by using a contact mask to form the bit line contact hole 21. The bit line contact hole 21 may have a circular shape or an elliptical shape from the perspective of a plan view. A portion of the substrate 11 may be exposed through the bit line contact hole 21. The bit line contact hole 21 may have a diameter which is controlled to have a predetermined line width. The bit line contact hole 21 may have a shape that exposes a portion of the active region 13. For example, the first impurity region 19 may be exposed by the bit line contact hole 21. The bit line contact hole 21 may have a diameter which is greater than the width of a minor axis of the active region 13. Accordingly, in an etching process for forming the bit line contact hole 21, the first impurity region 19, the isolation layer 12, and a portion of the gate capping layer 18 may be etched. In other words, the gate capping layer 18, the first impurity region 19 and the isolation layer 12 below the bit line contact hole 21 may be recessed to a predetermined depth. As a result, the bottom portion of the bit line contact hole 21 may extend into the inside of the substrate 11. As the bit line contact hole 21 expands, the surface of the first impurity region 19 may be recessed, and the surface of the first impurity region 19 may be positioned at a lower level than the surface of the substrate 11.

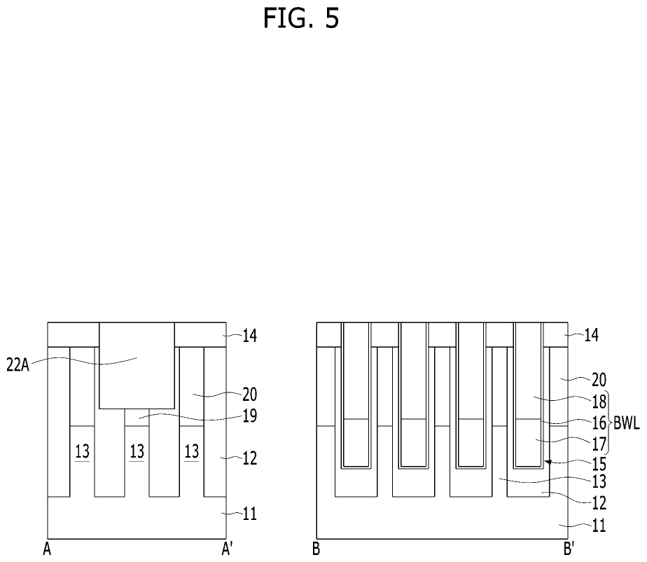

Referring to FIG. 5, a preliminary plug 22A may be formed. The preliminary plug 22A may be formed by a Selective Epitaxial Growth (SEG) process. For example, the preliminary plug 22A may include an epitaxial layer which is doped with phosphorous, i.e., SEG SiP. Through the selective epitaxial growth, the preliminary plug 22A may be formed without voids. According to another embodiment of the present invention, the preliminary plug 22A may be formed by depositing a polysilicon layer and performing a Chemical Mechanical Polishing (CMP) process. The preliminary plug 22A may fill the bit line contact hole 21. The upper surface of the preliminary plug 22A may be positioned at the same level as the upper surface of the hard mask layer 14.

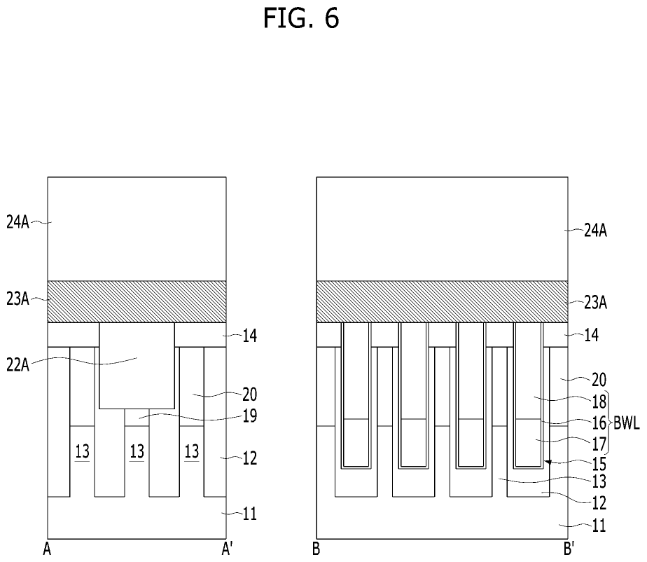

Referring to FIG. 6, a bit line conductive layer 23A and a bit line hard mask layer 24A may be stacked. The bit line conductive layer 23A and the bit line hard mask layer 24A may be sequentially stacked over the preliminary plug 22A and the hard mask layer 14. The bit line conductive layer 23A may include a metal-containing material. The bit line conductive layer 23A may include a metal, a metal nitride, a metal silicide, or a combination thereof. According to the embodiment of the present invention, the bit line conductive layer 23A may include tungsten (W). According to another embodiment of the present invention, the bit line conductive layer 23A may include a stack (TiN/W) of titanium nitride and tungsten. In this case, the titanium nitride may function as a barrier. The bit line hard mask layer 24A may be formed of a dielectric material having an etch selectivity with respect to the bit line conductive layer 23A and the preliminary plug 22A. The bit line hard mask layer 24A may include silicon oxide or silicon nitride. According to the embodiment of the present invention, the bit line hard mask layer 24A may be formed of silicon nitride.

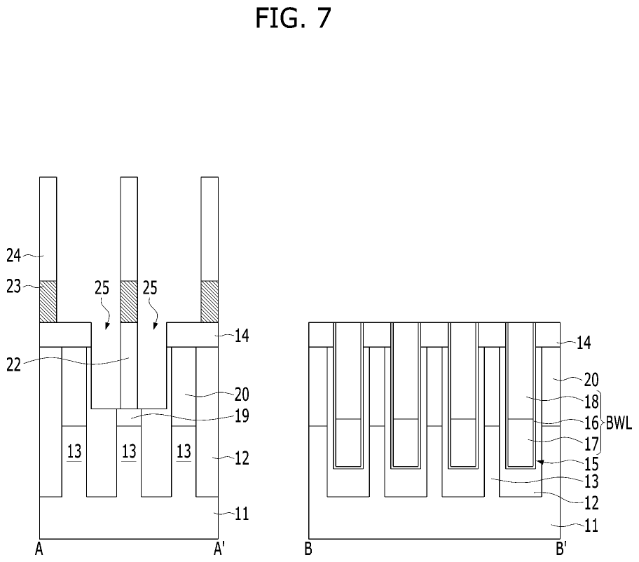

Referring to FIG. 7, a bit line 23 and a bit line contact plug 22 may be formed. The bit line 23 and the bit line contact plug 22 may be formed by an etching process using a bit line mask layer.

The bit line hard mask layer 24A and the bit line conductive layer 23A may be etched by using the bit line mask layer as an etch barrier. As a result, the bit line 23 and the bit line hard mask 24 may be formed. The bit line 23 may be formed by etching the bit line conductive layer 23A. The bit line hard mask 24 may be formed by etching the bit line hard mask layer 24A.

Subsequently, the preliminary plug 22A may be etched to have the same line width as that of the bit line 23. As a result, the bit line contact plug 22 may be formed. The bit line contact plug 22 may be formed over the first impurity region 19. The bit line contact plug 22 may couple the first impurity region 19 and the bit line 23 to each other. The bit line contact plug 22 may be formed in the bit line contact hole 21. The line width of the bit line contact plug 22 may be smaller than the diameter of the bit line contact hole 21. Accordingly, gaps 25 may be defined on both sides of the bit line contact plug 22.

As described above, since the bit line contact plug 22 is formed, the gaps 25 may be formed in the bit line contact hole 21. This is because the bit line contact plug 22 is formed by being etched to be smaller than the diameter of the bit line contact hole 21. The gap 25 may not be formed to have a shape surrounding the bit line contact plug 22, but may be independently formed on both sidewalls of the bit line contact plug 22. As a result, one bit line contact plug 22 and a pair of the gaps 25 may be positioned in the bit line contact hole 21, and a pair of the gaps 25 may be isolated by the bit line contact plug 22. The bottom surface of the gaps 25 may extend into the inside of the isolation layer 12. The bottom surface of the gaps 25 may be positioned at a lower level than the recessed top surface of the first impurity region 19.

A structure in which the bit line contact plug 22, the bit line 23, and the bit line hard mask 24 are stacked in the mentioned order may be referred to as a bit line structure. From the perspective of a top view, in other words, as shown in FIG. 1, the bit line structure BL may be a line-shaped pattern structure which extends long in the first direction D1.

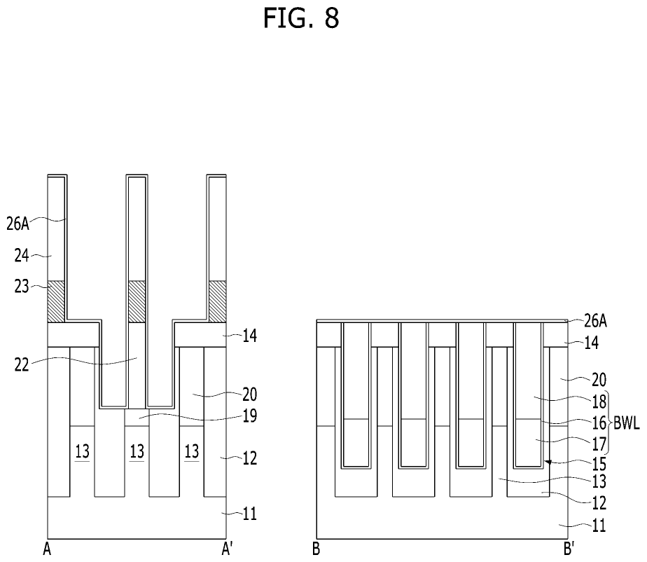

Referring to FIG. 8, a first spacer layer 26A may be formed. The first spacer layer 26A may include silicon nitride.

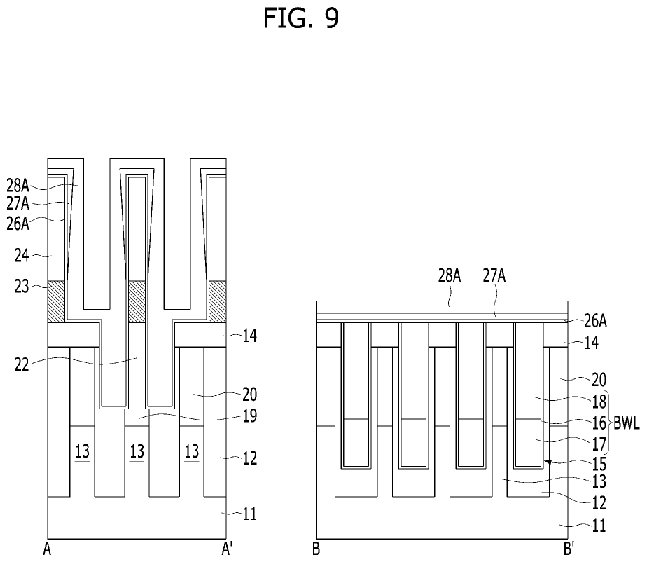

Referring to FIG. 9, a buffer layer 27A and a gap-fill material layer 28A may be sequentially formed over the first spacer layer 26A. The buffer layer 27A may cover the upper end portion and the sidewalls of the upper end portion of the bit line hard mask 24 over the first spacer layer 26A. The buffer layer 27A may have an overhang shape and the buffer layer 27A may be formed non-conformally. Thus, the buffer layer 27A may not be positioned on both sidewalls of the bit line 23. The buffer layer 27A may include silicon oxide.

The gap-fill material layer 28A may fill the gap 25. The gap-fill material layer 28A and the first spacer layer 26A may be formed of the same material, but the gap-fill material layer 28A may be thicker than the first spacer layer 26A. The gap-fill material layer 28A may include silicon nitride.

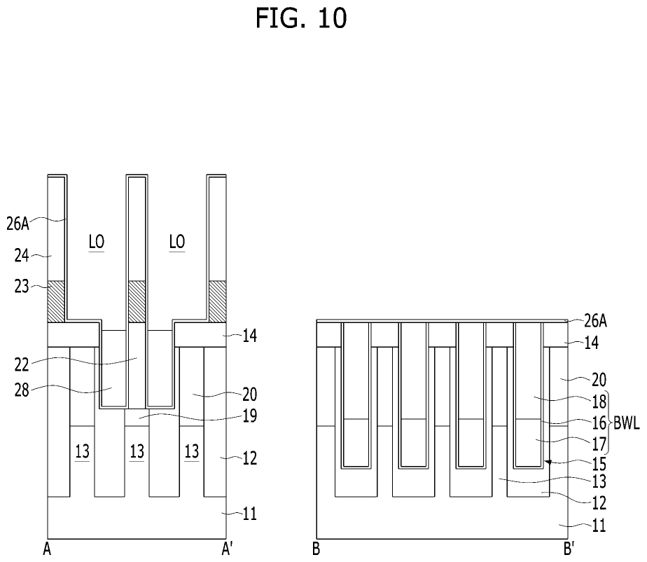

Referring to FIG. 10, a gap-fill spacer 28 filling the gap 25 may be formed. A trimming process of the gap-fill material layer 28A may be performed to form the gap-fill spacers 28. The trimming process of the gap-fill material layer 28A may be performed by an etch-back process, and the buffer layer 27A may protect the sidewalls of the upper end portion of the first spacer layer 26A.

After the gap-fill spacer 28 is formed, the buffer layer 27A may be removed.

The upper surface of the gap-fill spacer 28 may be positioned at a lower level than the upper surface of the bit line contact plug 22. According to another embodiment of the present invention, the upper surface of the gap-fill spacer 28 and the upper surface of the bit line contact plug 22 may be positioned at the same level.

The gaps 25 may be filled with a double layer of the first spacer layer 26A and the gap-fill spacer 28. The gap-fill spacer 28 may be referred to as a dielectric plug or a plugging spacer. According to another embodiment of the present invention, the gap-fill spacer 28 may be formed of silicon oxide or a low-k material.

After the gap-fill spacer 28 is formed, a line-type opening LO may be defined between the neighboring bit lines 23. A single layer of the first spacer layer 26A may remain on both sidewalls of the bit line 23 and the bit line hard mask 24. A bi-layer of the first spacer layer 26A and the gap-fill spacer 28 may remain on both sidewalls of the bit line contact plug 22.

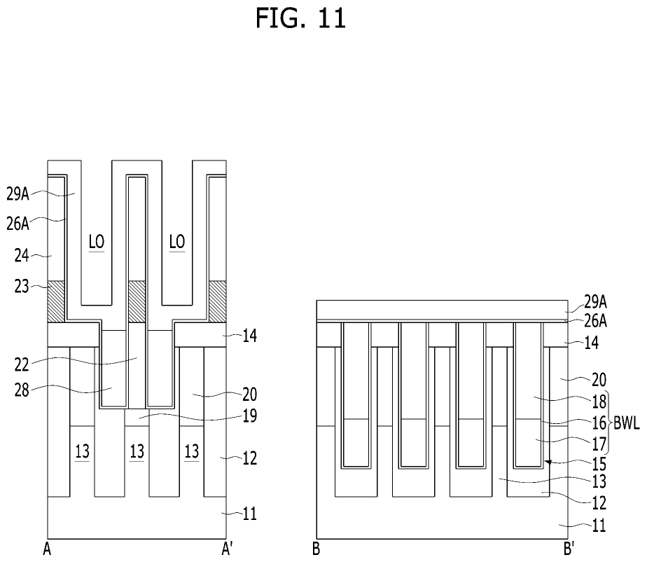

Referring to FIG. 11, a sacrificial spacer layer 29A may be formed over the gap-fill spacer 28 and the first spacer layer 26A. The sacrificial spacer layer 29A and the first spacer layer 26A may include the same material. For example, the sacrificial spacer layer 29A may include silicon nitride.

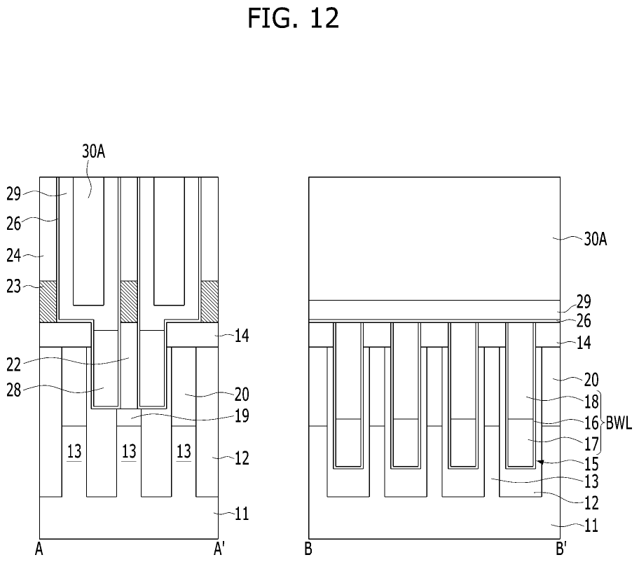

Referring to FIG. 12, a sacrificial layer 30A may be formed over the sacrificial spacer layer 29A. The sacrificial layer 30A may fill between the bit line structures and may include silicon oxide, such as Spin-On-Dielectric (SOD) material.

Subsequently, the sacrificial layer 30A and the sacrificial spacer layer 29A may be planarized to expose the upper surface of the bit line hard mask 24. After the sacrificial layer 30A is planarized, the sacrificial spacers 29 may be positioned between the bit line structures.

After the planarization process of the sacrificial layer 30A, a portion of the first spacer layer 26A may be planarized to form a first spacer 26.

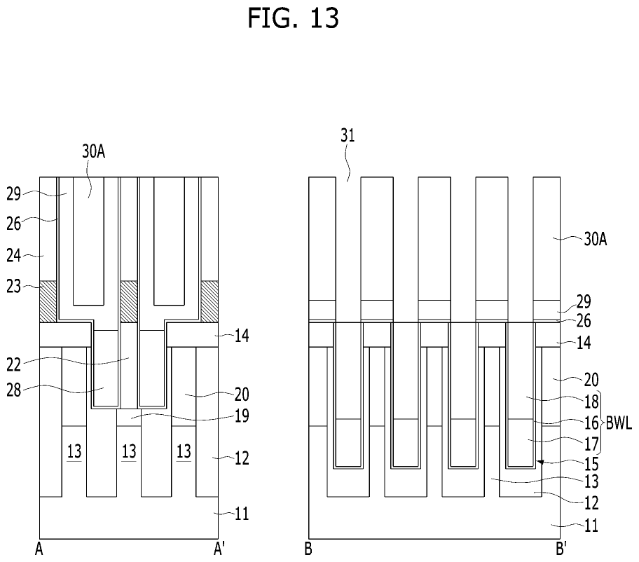

Referring to FIG. 13, hole-shaped openings 31 may be formed in the sacrificial layer 30A. The hole-shaped openings 31 may be formed by etching the sacrificial layer 30A. In the extending direction of the bit line 23, in other words, between the neighboring bit line structures, the hole-shaped openings 31 and the sacrificial layers 30A may be alternately formed. The hole-shaped openings 31 may have a rectangular hole shape from the perspective of a top view.

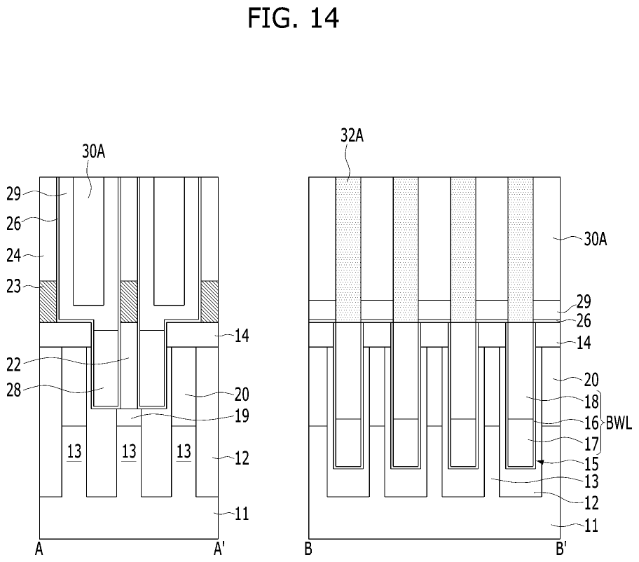

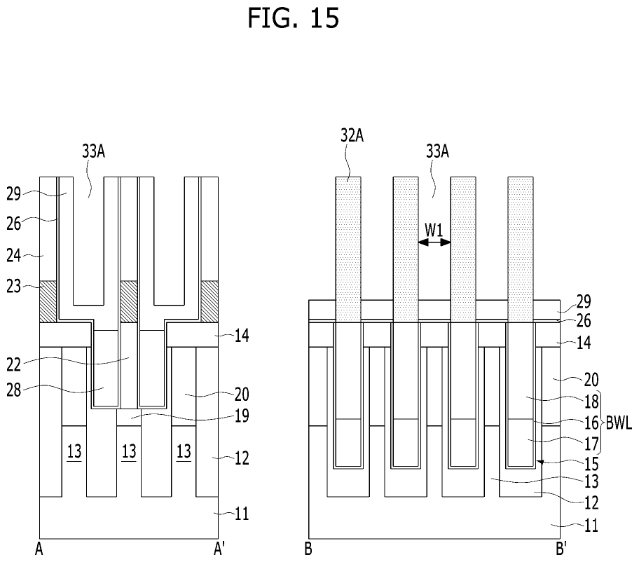

Referring to FIG. 14, a plug isolation layer 32A filling the hole-shaped openings 31 may be formed. The plug isolation layers 32A may include silicon nitride or a low-k material. According to another embodiment of the present invention, the plug isolation layers 32A may include boron-containing silicon nitride.

Referring to FIG. 15, the sacrificial layers 30A may be removed. Accordingly, a plurality of initial contact openings 33A may be formed between the plug isolation layers 32A. The initial contact openings 33A may be formed in the sacrificial spacers 29 between the bit line structures. The initial contact openings 33A may have a first line width W1. From the perspective of a top view, the initial contact openings 33A may have a rectangular hole shape, such as a square or a rectangle.

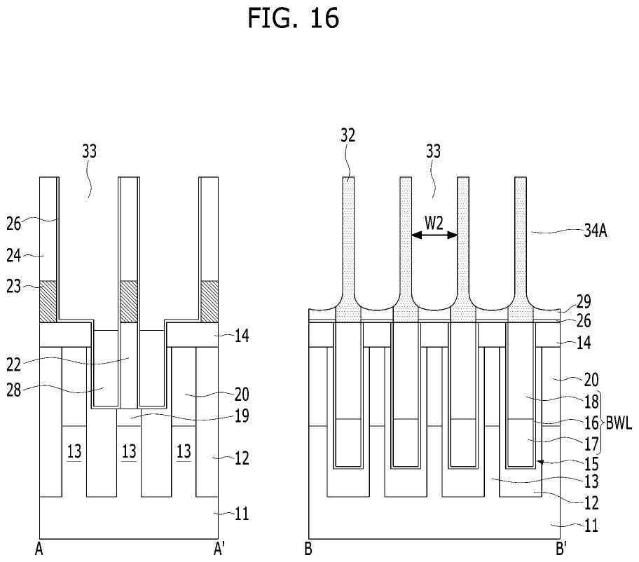

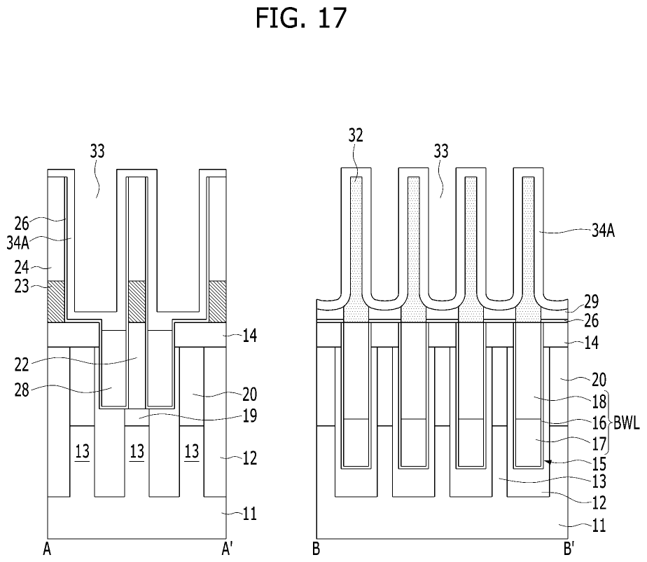

Referring to FIG. 16, the sacrificial spacer 29 and the plug isolation layers 32A may be trimmed. The sacrificial spacer 29 and the plug isolation layers 32A may be trimmed by an etch-back process. As a result of the trimming process, the contact openings 33 may be formed. The contact openings 33 may have a second line width W2. The contact openings 33 may be obtained by expansion of the initial contact openings 33A.

All of the sacrificial spacers 29 between the bit line structures may be removed, and the sacrificial spacers 29 below the contact openings 33 may be recessed. According to another embodiment of the present invention, all of the sacrificial spacers 29 below the contact openings 33 may be removed.

Referring to FIG. 17, a metallic sacrificial material layer 34A may be formed over the contact openings 33. The metallic sacrificial material layer 34A may be conformally formed over the sacrificial spacers 29 and the plug isolation layers. The metallic sacrificial material layer 34A may include titanium nitride.

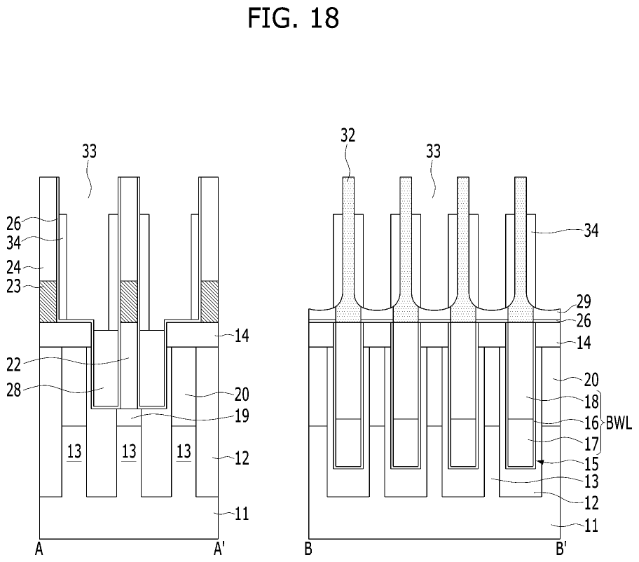

Referring to FIG. 18, a metallic sacrificial spacer 34 may be formed. In order to form the metallic sacrificial spacer 34, the metallic sacrificial material layer 34A may be etched.

The metallic sacrificial spacer 34 may have a shape surrounding the sidewalls of the contact opening 33. The upper surface of the metallic sacrificial spacer 34 may be positioned at a lower level than the upper surface of the bit line hard mask 24. The metallic sacrificial spacer 34 may be thicker than the first spacer 26.

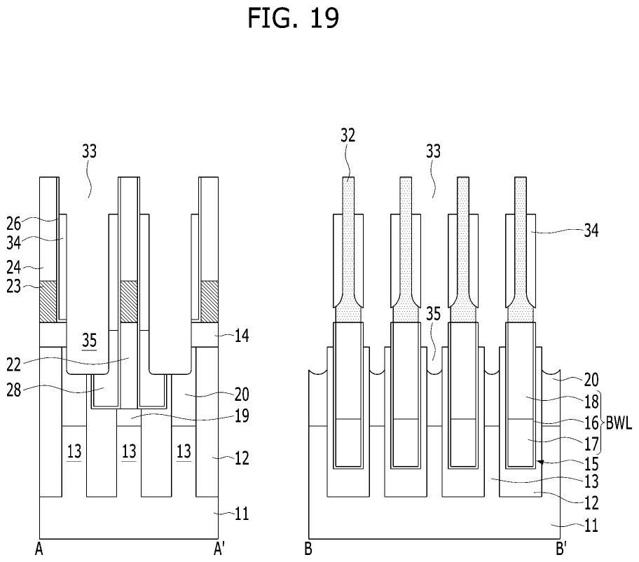

Referring to FIG. 19, the lower materials (e.g., materials/layers located below the contact openings 33) may be etched. The lower materials may be etched to be self-aligned to the contact openings 33. As a result, a plurality of recess regions 35 exposing a portion of the active region 13 may be formed between the bit line structures. Anisotropic etching or a combination of anisotropic etching and isotropic etching may be used to form the recess regions 35. For example, among the structures exposed through the contact openings 33 between the bit line structures, the first spacer 26, the hard mask layer 14, and the gap-fill spacer 28 may be sequentially and anisotropically etched, and then a portion of the exposed active region 13 may be isotropically etched. Portions of the active region 13 and the gap-fill spacer 28 may be exposed by the recess regions 32.

The recess regions 35 may extend into the inside of the substrate 11. While the recess regions 35 are formed, the isolation layer 12 and the second impurity region 20 may be recessed to a predetermined depth. The bottom surfaces of the recess regions 35 may be positioned at a lower level than the upper surface of the bit line contact plug 22. The bottom surfaces of the recess regions 35 may be positioned at a higher level than the bottom surface of the bit line contact plug 22. The contact openings 33 and the recess regions 35 may be coupled to each other. The vertical structure of the contact openings 33 and the recess regions 35 may be referred to as ‘storage node contact holes’.

After the recess regions 35 are formed, the double layer of the first spacer 26 and the metallic sacrificial spacer 34 may remain on the sidewalls of the bit line structure, and a single layer of the metallic sacrificial spacer 34 may remain on the sidewalls of the plug isolation layers 32.

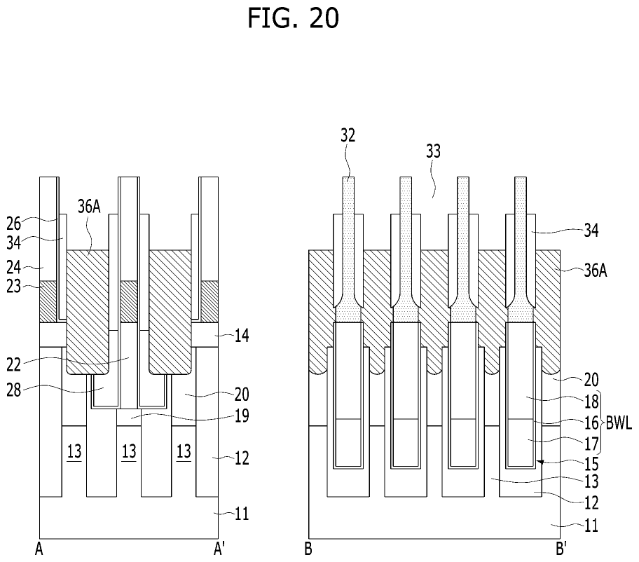

Referring to FIG. 20, lower plug layers 36A may be formed over the metallic sacrificial spacer 34. The lower plug layers 36A may completely fill the recess regions 35 and may partially fill the contact openings 33. The lower plug layers 36A may contact the second impurity region 20. The lower plug layers 36A may be positioned adjacent to the bit line structure. From the perspective of a top view, a plurality of lower plug layers 36A may be positioned between a plurality of bit line structures. In a direction parallel to the bit line 23, a plurality of the lower plug layers 36A and a plurality of the plug isolation layers 32 may be alternately positioned between the neighboring bit line structures.

The lower plug layers 36A may include a silicon-containing material. The lower plug layers 36A may include polysilicon, and the polysilicon may be doped with an impurity. The lower plug layers 36A may be coupled to the second impurity region 20. The upper surface of the lower plug layers 36A may be higher than the upper surface of the bit line 23. After polysilicon is deposited to fill the contact openings 33 and the recess regions 35 to form the lower plug layers 36A, planarization and etch-back processes may be sequentially performed.

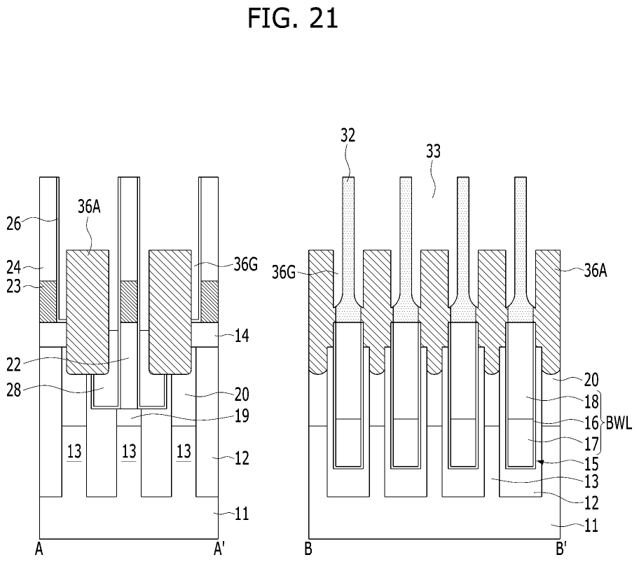

Referring to FIG. 21, the metallic sacrificial spacer 34 may be removed. Accordingly, the metallic sacrificial spacer 34 may be removed from the area between the lower plug layer 36A and the bit line 23 and, also, the metallic sacrificial spacer 34 may be removed from the area between the plug isolation layers 32 and the lower plug layers 36A.

The space from which the metallic sacrificial spacer 34 is removed may be simply referred to as an ‘air gap 36G’.

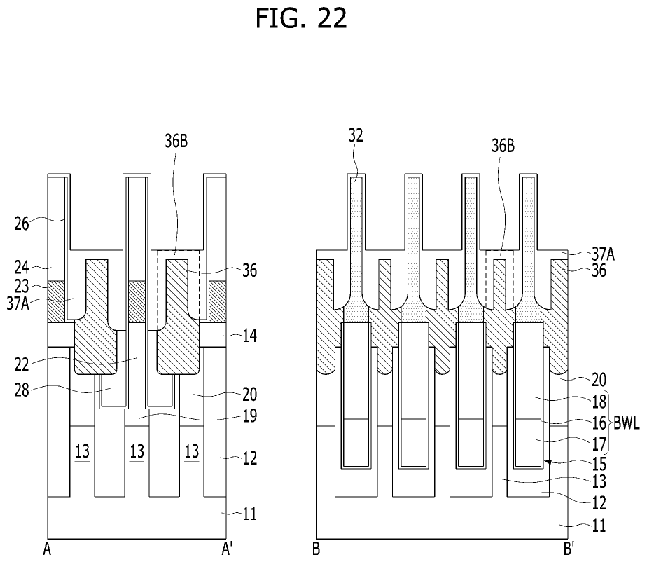

Referring to FIG. 22, a second spacer layer 37A filling the air gap 36G may be formed. The second spacer layer 37A may include silicon oxide. The second spacer layer 37A may be formed by selectively oxidizing portions of the lower plug layer 36A. The second spacer layer 27A may be formed by oxidizing portions of the first spacer layer 26A and the plug isolation layers 32.

The oxidation process for forming the second spacer layer 37A may include radical oxidation and/or dry oxidation. For example, radical oxidation may be first performed to form the second spacer layer 37A, and then dry oxidation may be sequentially performed. According to another embodiment of the present invention, in order to form the second spacer layer 37A, dry oxidation may be performed after an ultra low temperature oxide (ULTO) is thinly deposited.

During the formation of the second spacer layer 37A, portions 36B of the lower plug layers 36A may be lost and oxidized. The lower plug layers 36A may remain as indicated by a reference numeral ‘36’, which will be simply referred to as ‘lower plugs 36,’ hereinafter.

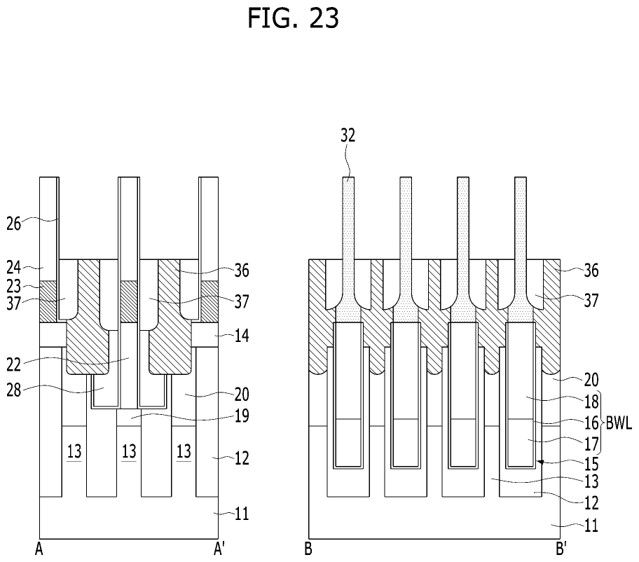

Referring to FIG. 23, a second spacer 37 may be formed. The second spacer 37 may be formed by selectively etching the second spacer layer 37A. The upper surface of the second spacer 37 may be positioned at the same level as the upper surface of the lower plugs 36.

The second spacer 37 may be positioned between the lower plug 36 and the bit line 23 with the first spacer 26 interposed therebetween and, also, may be positioned between the plug isolation layer 32 and the lower plugs 36.

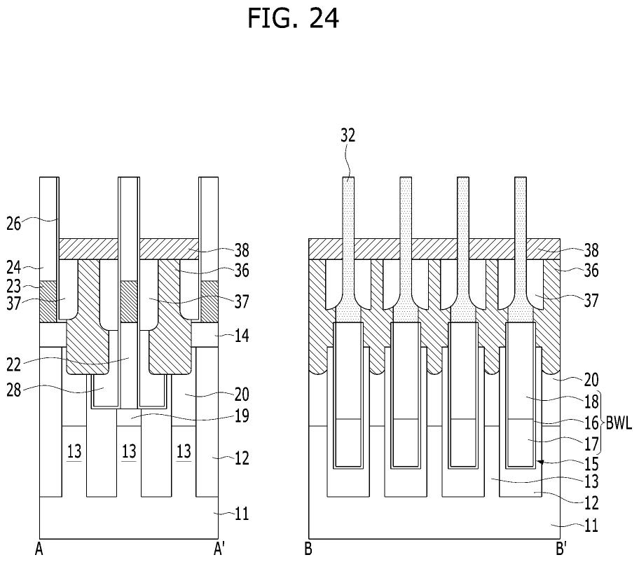

Referring to FIG. 24, the upper plugs 38 may be formed. The lower plugs 36 and the upper plugs 38 may be formed of the same material. The upper plugs 38 may include polysilicon. The line width of the upper plugs 38 may be greater than the line width of the lower plugs 36. The upper plugs 38 may be formed by depositing polysilicon and performing an etch-back process.

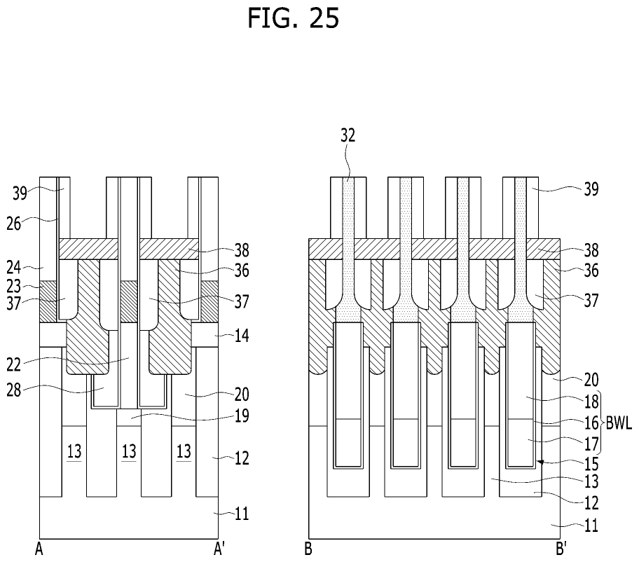

Referring to FIG. 25, a contact spacer 39 may be formed over the upper plugs 38. The contact spacer 39 may include silicon oxide. The contact spacer 39 may be formed by depositing silicon oxide and performing an etch-back process. The contact spacer 39 may partially expose the upper surfaces of the upper plug 38. The contact spacer 39 may be formed on the sidewalls of the plug isolation layer 32 over the upper plug 38. Also, the contact spacer 39 may be formed over the first spacer 26 over the upper plug 38.

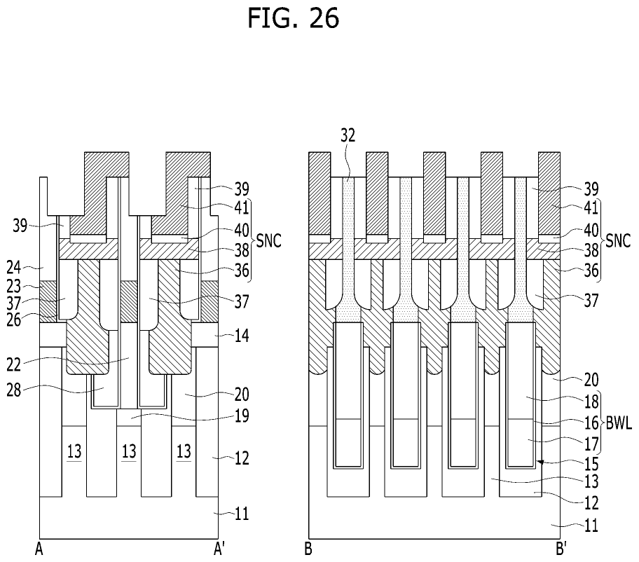

Referring to FIG. 26, an ohmic contact layer 40 may be formed over the upper plug 38. The ohmic contact layer 40 may include a metal silicide. Deposition and annealing of a silicidable metal layer may be performed to form the ohmic contact layer 40. As a result, silicidation may occur at the interface between the silicided metal layer and the upper plug 38 so as to form a metal silicide layer. The ohmic contact layer 40 may include cobalt silicide. According to the embodiment of the present invention, the ohmic contact layer 40 may include ‘CoSi₂ phase’ cobalt silicide.

When cobalt silicide of the CoSi2 phase is formed as the ohmic contact layer 40, contact resistance may be improved while forming cobalt silicide of a low resistance.

A landing pad 41 may be formed over the ohmic contact layer 40. The landing pad 41 may be formed by depositing a metal-containing layer and performing an etching process. The landing pad 41 may include a metal. The landing pad 41 may include a tungsten-containing material. The landing pad 41 may include a tungsten layer or a tungsten compound. The landing pad 41 may have a stacked structure of a titanium nitride liner layer and a tungsten layer. The upper end portion of the landing pad 41 may extend to overlap with the upper surface of the bit line hard mask 24.

The lower plug 36, the upper plug 38, the ohmic contact layer 39, and the landing pad 41 may form the storage node contact plug SNC.

As described above, the first spacer 26 and the gap-fill spacer 28 may be positioned between the bit line contact plug 22 and the lower plug 36. The first spacer 26 and the second spacer 37 may be positioned between the bit line 23 and the lower plug 36. Since the first spacer 26 includes silicon nitride and the second spacer 37 includes silicon oxide, a spacer structure having a nitride-oxide (NO) structure may be formed between the bit line 23 and the lower plug 36. The second spacer 37 may be thicker than the first spacer 26.

The first spacer 26 may be positioned between the upper plug 38 and the bit line hard mask 24.

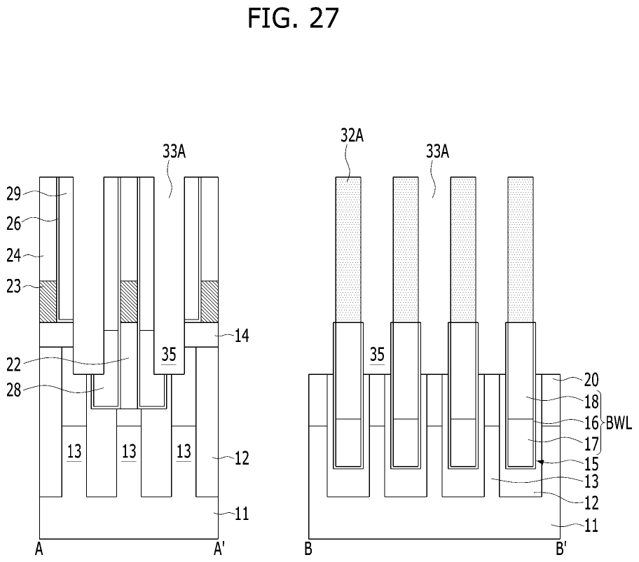

FIGS. 27 to 32 are cross-sectional views illustrating a method for fabricating a semiconductor device in accordance with another embodiment of the present invention. Hereinafter, the process illustrated in FIGS. 27 to 32 may proceed similarly to the process illustrated in FIGS. 3 to 26.

First, as illustrated in FIGS. 3 to 15, a plurality of initial contact openings 33A may be formed between the plug isolation layers 32A. The initial contact opening 33A may be formed in the sacrificial spacer 29 between the bit line structures. The initial contact openings 33A may have a rectangular hole shape when viewed from a top view.

Subsequently, referring to FIG. 27, the lower materials below the initial contact openings 33A may be etched. The lower materials may be etched to be self-aligned to the initial contact openings 33A. As a result, a plurality of recess regions 35 exposing a portion of the active region 13 may be formed between the bit line structures. Anisotropic etching or a combination of anisotropic etching and isotropic etching may be used to form the recess regions 35. For example, among the structures exposed through the initial contact openings 33A between the bit line structures, the first spacer 26, the hard mask layer 14, the gap-fill spacer 28, and the sacrificial spacer 29 may be anisotropically etched, and a portion of the exposed active region 13 may be isotropically etched. Portions of the active region 13 and the gap-fill spacer 28 may be exposed by the recess regions 35.

The recess regions 35 may extend into the inside of the substrate 11. While the recess regions 35 are formed, the isolation layer 12 and the second impurity region 20 may be recessed to a predetermined depth. The bottom surfaces of the recess regions 35 may be positioned at a lower level than the upper surface of the bit line contact plug 22. The bottom surfaces of the recess regions 35 may be positioned at a higher level than the bottom surface of the bit line contact plug 22. The contact openings 33A and the recess regions 35 may be coupled to each other. The vertical structure of the contact openings 33A and the recess regions 35 may be referred to as ‘storage node contact holes’.

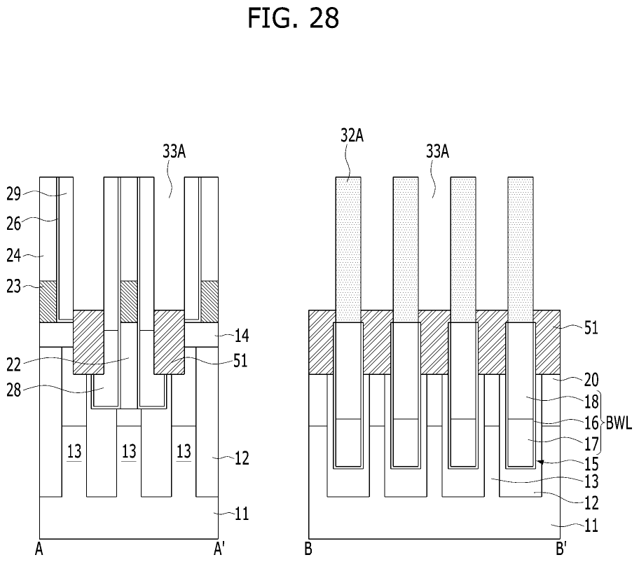

Referring to FIG. 28, a lower plug 51 may be formed. The lower plug 51 may completely fill the recess regions 35 and may partially fill the contact opening 33A. The lower plug 51 may contact the second impurity region 20. The lower plug 51 may be positioned adjacent to the bit line structure. From the perspective of a top view, a plurality of lower plugs 51 may be positioned between the bit line structures. In a direction parallel to the bit line 23, a plurality of lower plugs 51 and a plurality of plug isolation layers 32A may be alternately positioned between the neighboring bit line structures.

The lower plug 51 may include a silicon-containing material. The lower plug 51 may include polysilicon. Polysilicon may be doped with an impurity. The lower plug 51 may be coupled to the second impurity region 20. The upper surface of the lower plug 51 may be lower than the upper surface of the bit line 23. The lower plug 51 may be formed by depositing polysilicon to fill the contact opening 33 and the recess region 35 and sequentially performing planarization and etch-back processes.

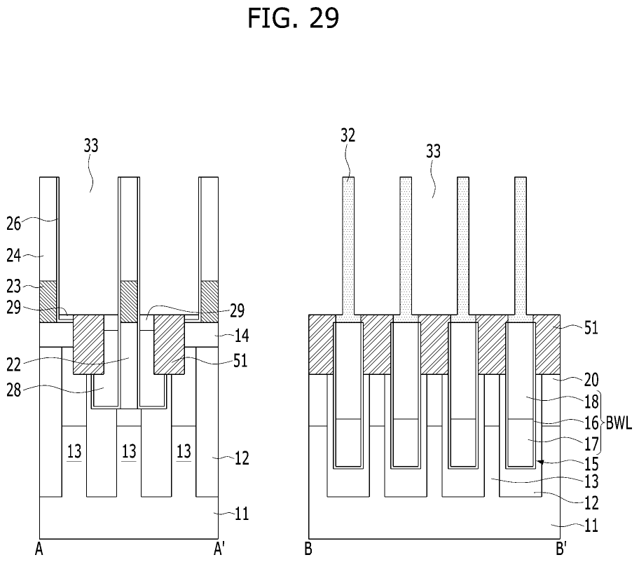

Referring to FIG. 29, the sacrificial spacer 29 and the plug isolation layers 32A may be trimmed. The trimming of the sacrificial spacer 29 and the plug isolation layers 32A may be performed by an etch-back process. The contact opening 33 may be formed by the trimming process. The contact opening 33 may be obtained by the expansion of the initial contact opening 33A.

A portion of the sacrificial spacer 29 may remain on the upper sidewalls of the lower plugs 51 in the A-A′ direction. In the B-B′ direction, the plug isolation layers 32A may be trimmed as indicated by a reference numeral ‘32’.

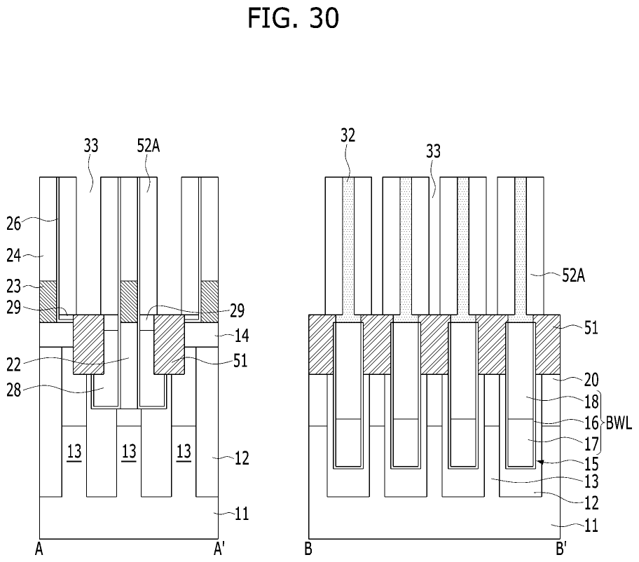

Referring to FIG. 30, a second spacer layer 52A may be formed. The second spacer layer 52A may be formed by a process of depositing silicon oxide and an etch-back process.

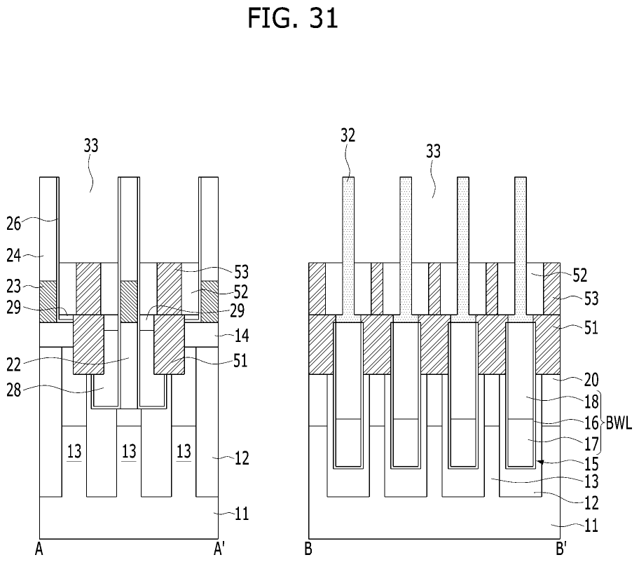

Referring to FIG. 31, a middle plug 53 may be formed over the second spacer layer 52A and the lower plug 51. The middle plug 53 may include a silicon-containing material. The middle plug 53 may include polysilicon, and the polysilicon may be doped with an impurity. The middle plug 53 may be formed over the lower plug 51. The upper surface of the middle plug 53 may be located at a higher level than the upper surface of the bit line 23. The middle plug 53 may be formed by depositing polysilicon to fill the remaining portion of the contact opening 33 and sequentially performing planarization and etch-back processes.

Subsequently, a second spacer 52 may be formed. The second spacer 52 may be formed by selectively etching the second spacer layer 52A. The upper surface of the second spacer 52 may be positioned at the same level as the upper surface of the middle plug 53.

The second spacer 52 may be positioned between the middle plug 53 and the bit line 23 with the first spacer 26 interposed therebetween. The second spacer 52 may also be positioned between the plug isolation layer 32 and the middle plug 53.

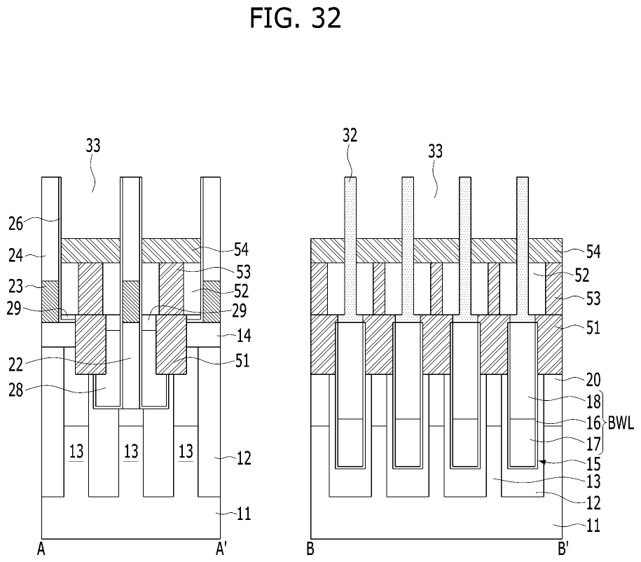

Referring to FIG. 32, an upper plug 54 may be formed. The upper plug 54 may include polysilicon. The line width of the upper plug 54 may be greater than the line width of the lower plug 51 and the middle plug 53.

Subsequently, as illustrated in FIGS. 25 and 26, a contact spacer 40 and a landing pad 41 may be formed.

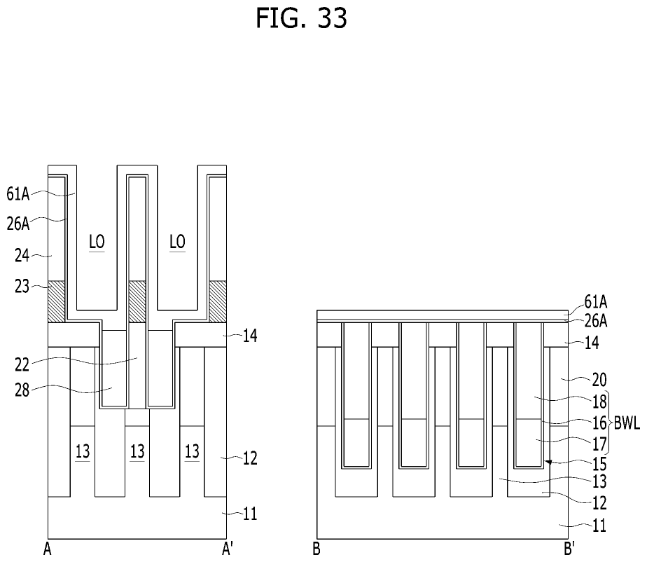

FIGS. 33 to 42 are cross-sectional views illustrating a method for fabricating a semiconductor device in accordance with another embodiment of the present invention. Hereinafter, the process illustrated in FIGS. 33 to 42 may proceed similarly to the process illustrated in FIGS. 3 to 26.

After the process of FIG. 10, as illustrated in FIG. 33, a metallic material layer 61A may be formed over the first spacer layer 26A. The metallic material layer 61A may be conformally formed. The metallic material layer 61A may include titanium nitride.

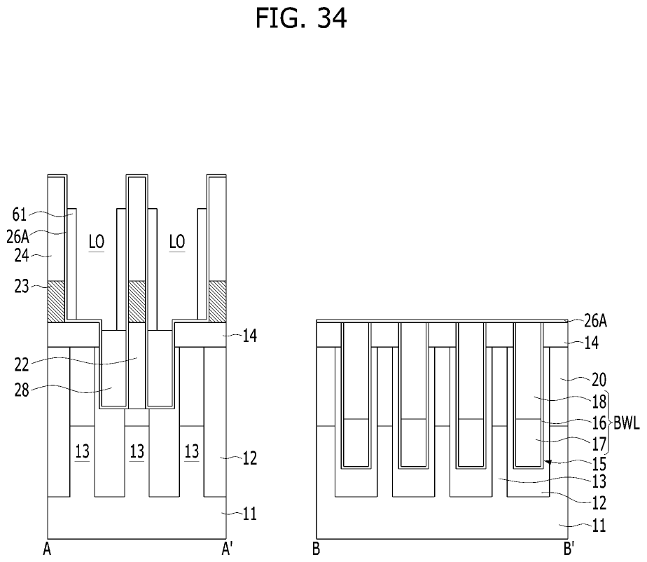

Referring to FIG. 34, metallic spacers 61 may be formed. In order to form the metallic spacers 61, the metallic material layer 61A may be etched.

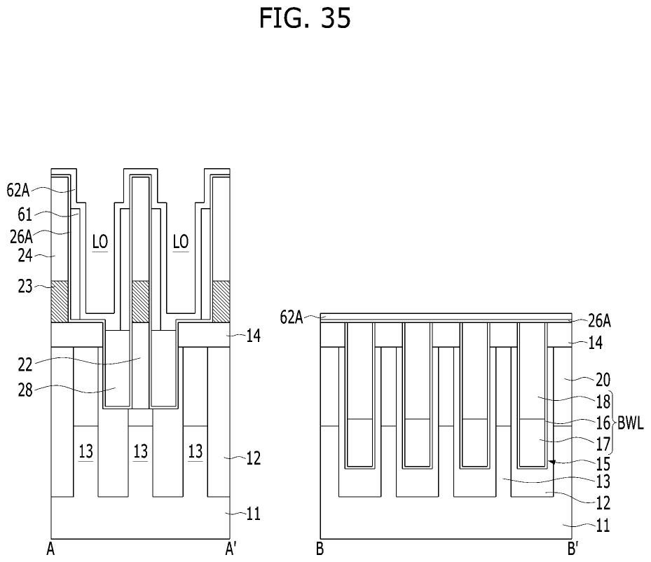

Referring to FIG. 35, a dielectric liner layer 62A may be formed over the metallic spacer 61. The dielectric liner layer 62A may include silicon nitride.

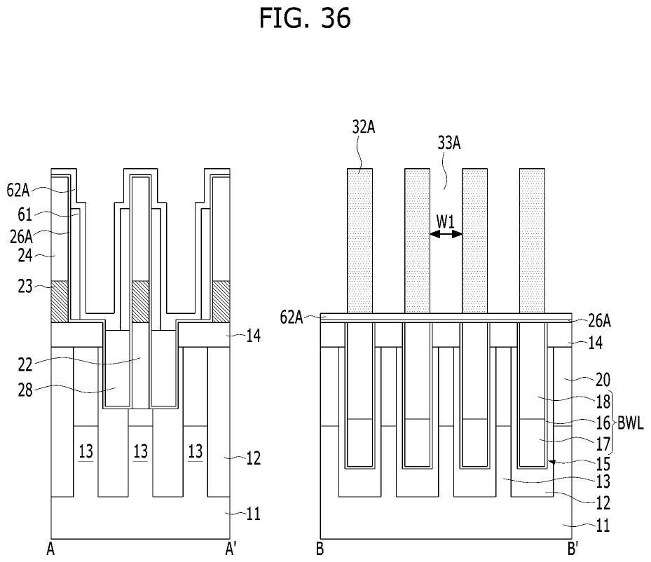

Subsequently, a series of processes as illustrated in FIGS. 12 to 15 may be performed over the dielectric liner layer 62A. As a result, as illustrated in FIG. 36, a plurality of initial contact openings 33A may be formed between the plug isolation layers 32A. The initial contact openings 33A may be positioned between the bit line structures. The initial contact openings 33A may have a first line width W1. The initial contact openings 33A may have a rectangular hole shape from the perspective of a top view.

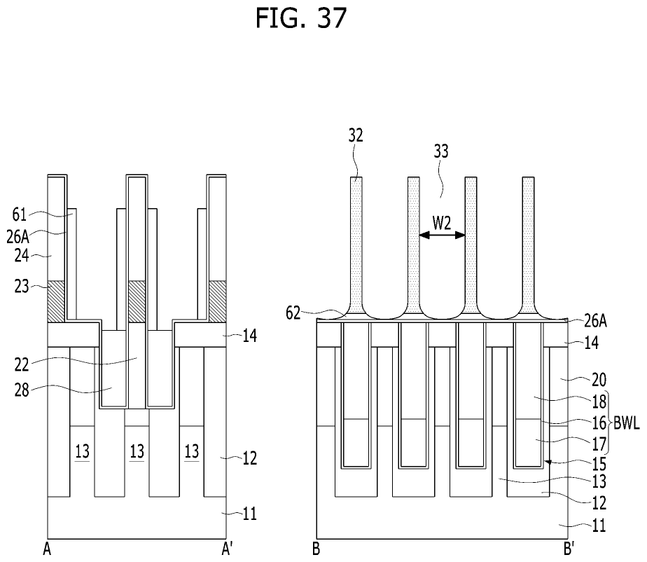

Referring to FIG. 37, the dielectric liner layer 62A and the plug isolation layers 32A may be trimmed. The trimming of the dielectric liner layer 62A and the plug isolation layers 32A may be performed by an etch-back process. As a result of the trimming process, the contact opening 33 may be formed. The contact opening 33 may have a second line width W2. The contact opening 33 may be obtained by the expansion of the initial contact opening 33A.

All of the dielectric liner layer 62A may be removed from the area between the bit line structures, and the dielectric liner layer 62A below the contact openings 33 may be recessed. After the dielectric liner layer 62A is removed, the metallic spacers 61 may remain on both sidewalls of the bit line 23. The dielectric liner pattern 62 may remain below the trimmed plug isolation layers 32.

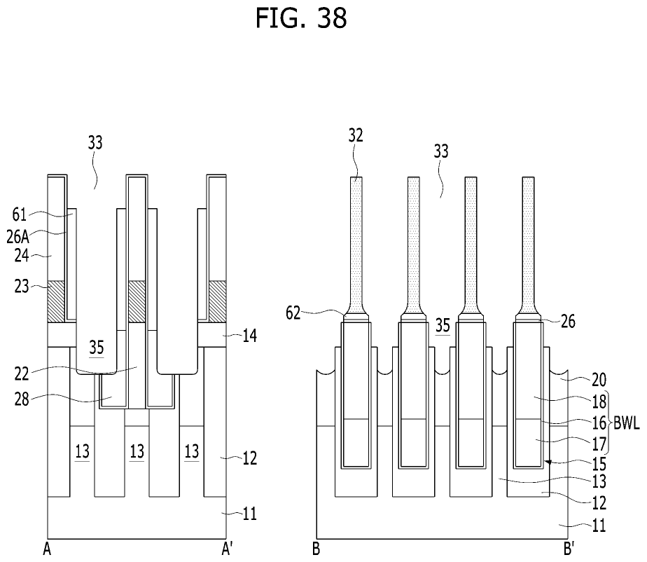

Referring to FIG. 38, the lower materials below the contact opening 33 may be etched. The lower materials may be etched to be self-aligned to the metallic spacer 61 and the plug isolation layer 32. As a result, a plurality of recess regions 35 exposing a portion of the active region 13 may be formed between the neighboring bit line structures. Anisotropic etching or a combination of anisotropic etching and isotropic etching may be used to form the recess regions 35. For example, the first spacer layer 26A, the hard mask layer 14, and the gap-fill spacer 28 may be sequentially and anisotropically etched among the structures that are exposed through the contact openings 33 between the bit line structures, and a portion of the active region 13 which is exposed thereafter may be isotropically etched. The recess regions 35 may expose portions of the active region 13 and the gap-fill spacer 28.

The recessed regions 35 may extend into the inside of the substrate 11. While the recess regions 35 are formed, the isolation layer 12 and the second impurity region 20 may be recessed to a predetermined depth. The bottom surface of the recess regions 35 may be positioned at a lower level than the upper surface of the bit line contact plug 22. The bottom surfaces of the recess regions 35 may be positioned at a higher level than the bottom surface of the bit line contact plug 22. The contact openings 33 and the recess regions 35 may be coupled to each other. The vertical structure of the contact openings 33 and the recess regions 35 may be referred to as ‘storage node contact holes’.

After the recess regions 35 are formed, a double layer of the first spacer 26 and the metallic spacer 61 may remain on the sidewalls of the bit line structure. The metallic spacer 61 may not remain on the sidewalls of the plug isolation layer 32. The dielectric liner layer 62 and the first spacer 26 may be positioned below the plug isolation layer 32.

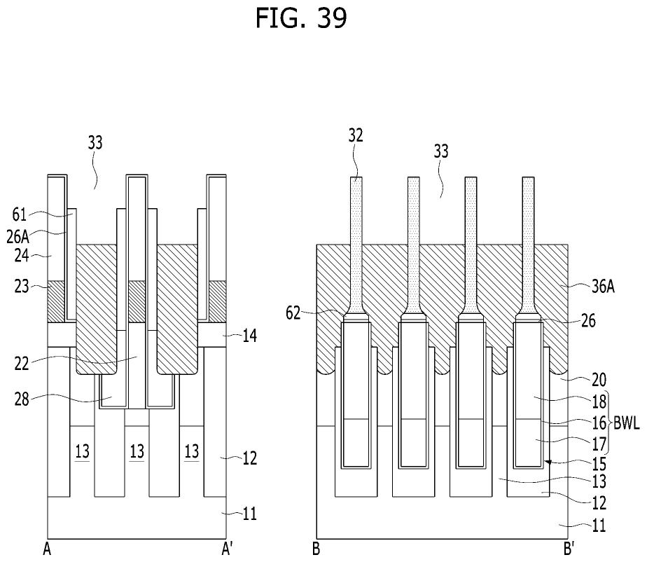

Referring to FIG. 39, a lower plug layer 36A may be formed. The lower plug layer 36A may completely fill the recess regions 35 and may partially fill the contact openings 33. The lower plug layer 36A may contact the second impurity region 20. The lower plug layer 36A may be positioned adjacent to the bit line structure. From the perspective of a top view, a plurality of the lower plug layers 36A may be positioned between the bit line structures. In a direction parallel to the bit line 23, a plurality of the lower plug layers 36A and a plurality of plug isolation layers 32 may be alternately positioned between the neighboring bit lines 23.

The lower plug layer 36A may include a silicon-containing material. The lower plug layer 36A may include polysilicon, and the polysilicon may be doped with an impurity. The lower plug layer 36A may be coupled to the second impurity region 20. The upper surface of the lower plug layer 36A may be higher than the upper surface of the bit line 23. The lower plug layer 36A may be formed by depositing polysilicon to fill the contact openings 33 and the recess regions 35 and sequentially performing planarization and etch-back processes.

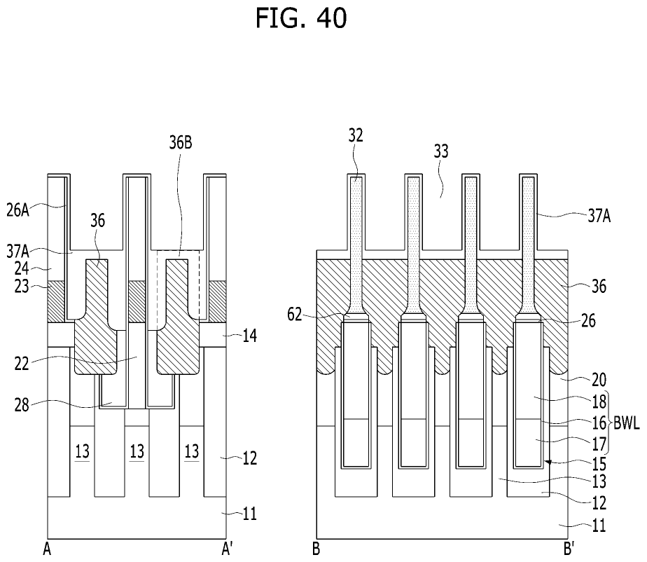

Referring to FIG. 40, the metallic spacer 61 may be removed. As a result, the metallic spacer 61 may be removed from the area between the lower plug layer 36A and the bit line 23.

Subsequently, a second spacer layer 37A filling the space from which the metallic spacer 61 is removed may be formed. The second spacer layer 37A may include silicon oxide. The second spacer layer 37A may be formed by selectively oxidizing portions of the lower plug layer 36A. The second spacer layer 27A may be formed by oxidizing the first spacer layer 26A and portions of the plug isolation layer 32.

The oxidation process for forming the second spacer layer 37A may include radical oxidation and/or dry oxidation. For example, radical oxidation may be first performed to form the second spacer layer 37A, and then dry oxidation may be sequentially performed. According to another embodiment of the present invention, in order to form the second spacer layer 37A, dry oxidation may be performed after a low-temperature oxide (ULTO) is thinly deposited.

During the formation of the second spacer layer 37A, portions 36B of the lower plug 36A may be lost and oxidized. The lower plug between the bit line structures may be trimmed as indicated by a reference numeral 36, and the lower plug between the plug isolation layers 32 may not be trimmed.

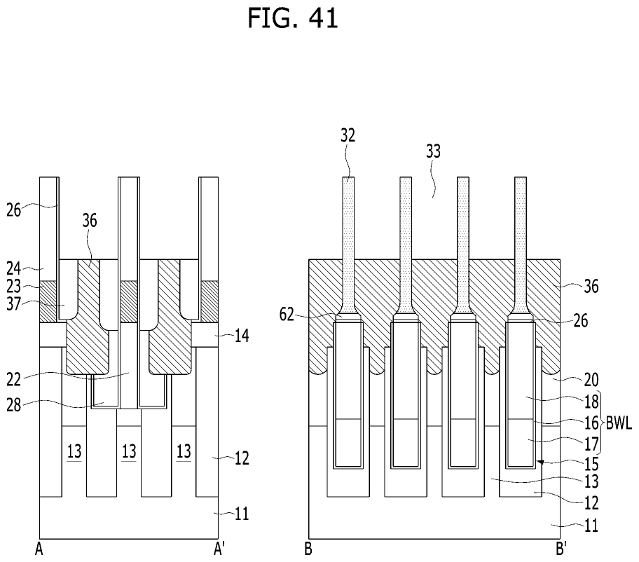

Referring to FIG. 41, a second spacer 37 may be formed. The second spacer 37 may be formed by selectively etching the second spacer layer 37A. The upper surface of the second spacer 37 may be positioned at the same level as the upper surface of the lower plug 36.

The second spacer 37 may be positioned between the lower plug 36 and the bit line 23 with the first spacer 26 interposed therebetween.

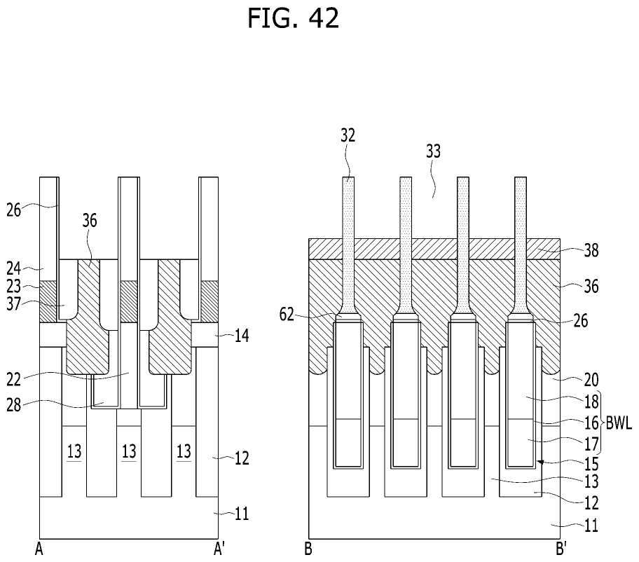

Referring to FIG. 42, the upper plug 38 may be formed. The upper plug 38 may include polysilicon. The line width of the upper plug 38 may be greater than the line width of the lower plug 36.

Subsequently, as illustrated in FIGS. 25 and 26, a contact spacer 40 and a landing pad 41 may be formed.

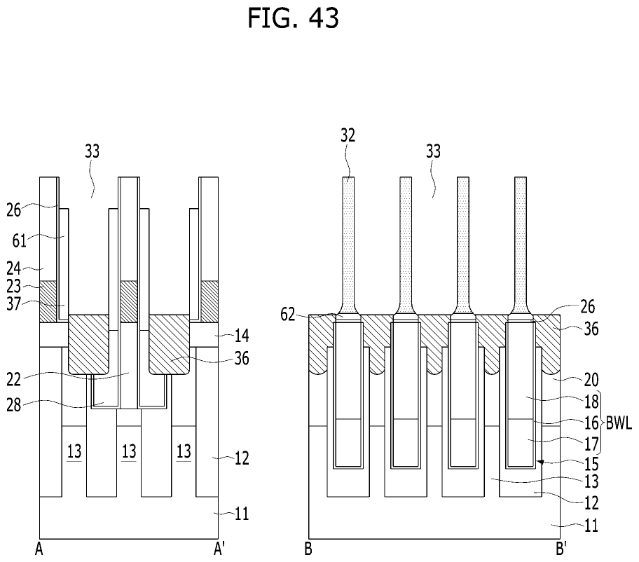

FIGS. 43 to 48 are cross-sectional views illustrating a method for fabricating a semiconductor device in accordance with another embodiment of the present invention. Hereinafter, the process illustrated in FIGS. 43 to 48 may proceed similarly to the process illustrated in FIGS. 3 to 26 and FIGS. 33 to 42.

Referring to FIGS. 33 to 37, a metallic spacer 61 may be formed over the first spacer layer 26A.

Subsequently, as illustrated in FIG. 43, the lower plug 36 may be formed. The lower plug 36 may completely fill the recess regions 35 and may partially fill the contact openings 33. The lower plug 36 may contact the second impurity region 20. The lower plug 36 may be positioned adjacent to the bit line structure. From the perspective of a top view, a plurality of the lower plugs 36 may be positioned between the bit line structures. In a direction parallel to the bit line 23, a plurality of the lower plugs 36 and a plurality of the plug isolation layers 32 may be alternately positioned between the neighboring bit lines 23.

The lower plug 36 may include a silicon-containing material. The lower plug 36 may include polysilicon, and the polysilicon may be doped with an impurity. The lower plug 36 may be coupled to the second impurity region 20. The upper surface of the lower plug 36 may be positioned at a lower level than the upper surface of the bit line 23. The lower plugs 36 may be formed by depositing polysilicon to fill the contact openings 33 and the recess regions 35 and sequentially performing planarization and etch-back processes.

Referring to FIG. 44, additional metallic spacers 63 may be formed. The additional metallic spacer 63 may have the same height as that of the metallic spacer 61. The additional metallic spacer 63 may have a shape surrounding the sidewalls of the plug isolation layer 32. The additional metallic spacer 63A may expose a portion of the lower plug 36.

A triple layer of the first spacer 26, the metallic spacer 61, and the additional metallic spacer 63 may be formed on both sidewalls of the bit line 23. A single layer of the additional metallic spacer 63 may be formed on the sidewall of the plug isolation layer 32.

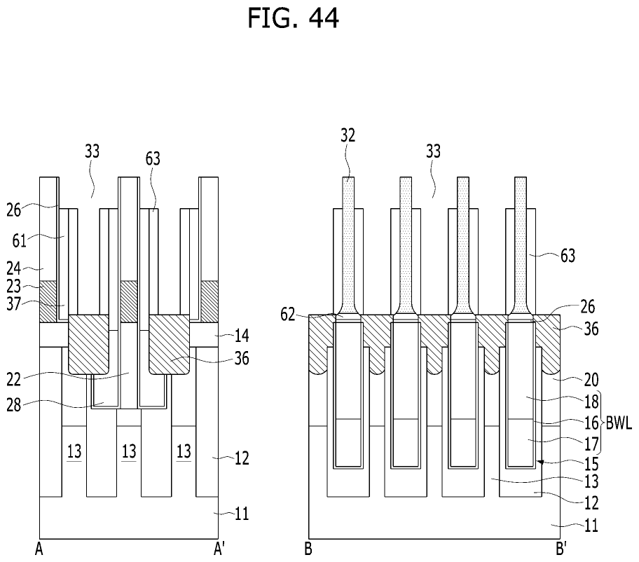

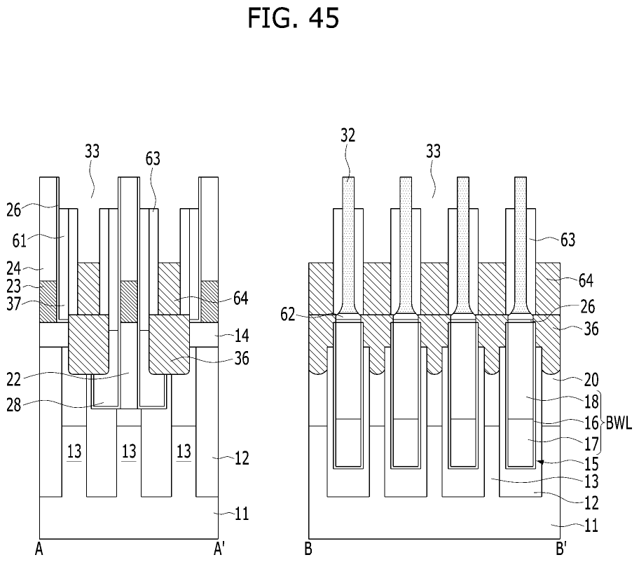

Referring to FIG. 45, a middle plug 64 may be formed. The middle plug 64 may be formed over the second metallic spacer 63 and the lower plug 36. The middle plug 64 may include a silicon-containing material. The middle plug 64 may include polysilicon, and the polysilicon may be doped with an impurity. The middle plug 64 may be formed over the lower plug 36. The upper surface of the middle plug 64 may be positioned at a higher level than the upper surface of the bit line 23. The middle plug 64 may be formed by depositing polysilicon to fill the remaining portion of the contact opening 33 and sequentially performing planarization and etch-back processes.

The metallic spacer 61 and the additional metallic spacer 63 may be positioned between the middle plug 64 and the bit line 23 with the first spacer 26 interposed therebetween. The additional metallic spacer 63 may be positioned between the plug isolation layer 32 and the middle plug 64.

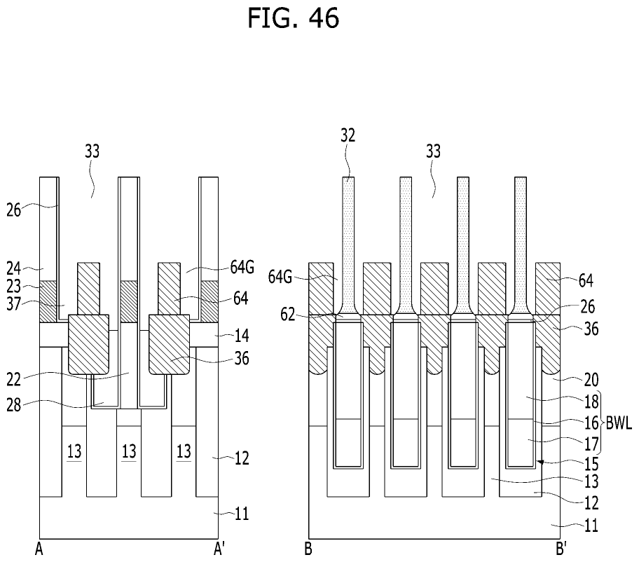

Referring to FIG. 46, the metallic spacer 61 and the additional metallic spacer 63 may be removed. As a result, the metallic spacer 61 and the additional metallic spacer 63 may be removed from the area between the middle plug 64 and the bit line 23 and, also, the additional metallic spacer 63 may be removed from the area between the plug isolation layer 32 and the middle plug 64. The metallic spacer 61 and the additional metallic spacer 63 may be removed to form an air gap 64G.

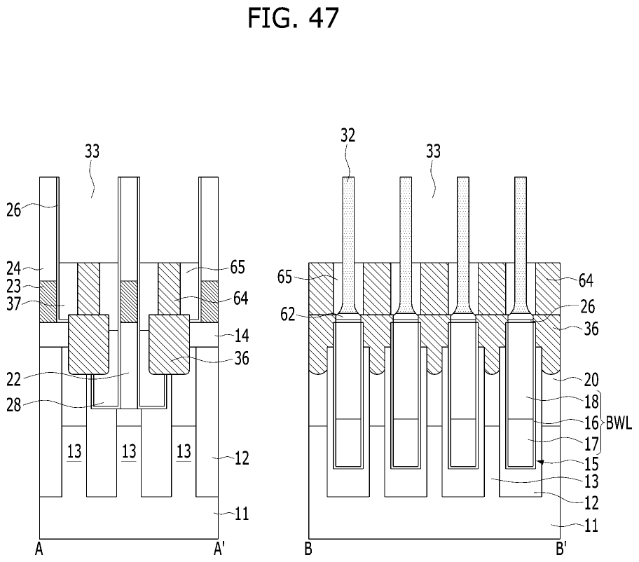

Referring to FIG. 47, a second spacer 65 may be formed to fill the air gaps 64G from which the metallic spacers are removed. The second spacer 65 may include silicon oxide. The second spacer 65 may be formed by selectively oxidizing portions of the middle plug 64.

The oxidation process for forming the second spacer 65 may include radical oxidation and/or dry oxidation. For example, radical oxidation may be first performed to form the second spacer 65, and then dry oxidation may be sequentially performed. According to another embodiment of the present invention, in order to form the second spacer 65, dry oxidation may be performed after a low-temperature oxide (ULTO) is thinly deposited.

During the formation of the second spacer 65, portions of the middle plug 64 may be lost and oxidized.

The upper surface of the second spacer 65 may be positioned at the same level as the upper surface of the middle plug 64.

The second spacer 65 may be positioned between the middle plug 64 and the bit line 23 with the first spacer 26 interposed therebetween and, also, may be positioned between the plug isolation layer 32 and the middle plug 64.

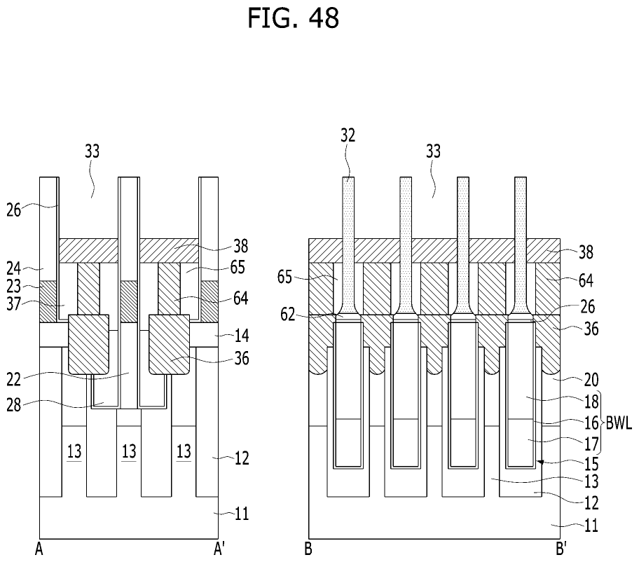

Referring to FIG. 48, the upper plug 38 may be formed. The upper plug 38 may include polysilicon. The line width of the upper plug 38 may be greater than the line width of the lower plug 36.

Subsequently, as illustrated in FIGS. 25 and 26, a contact spacer 40 and a landing pad 41 may be formed.

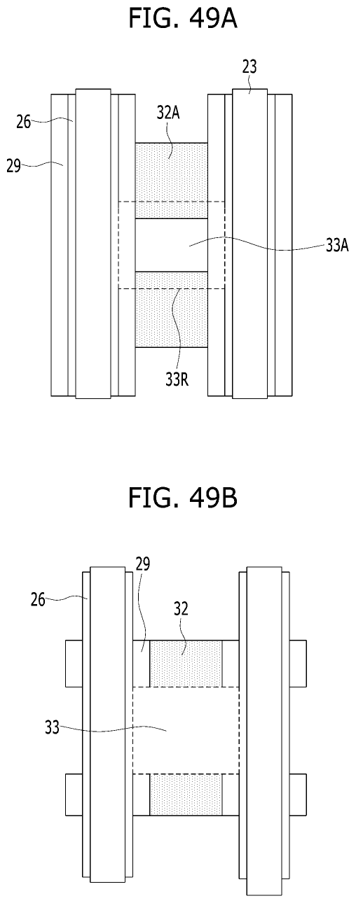

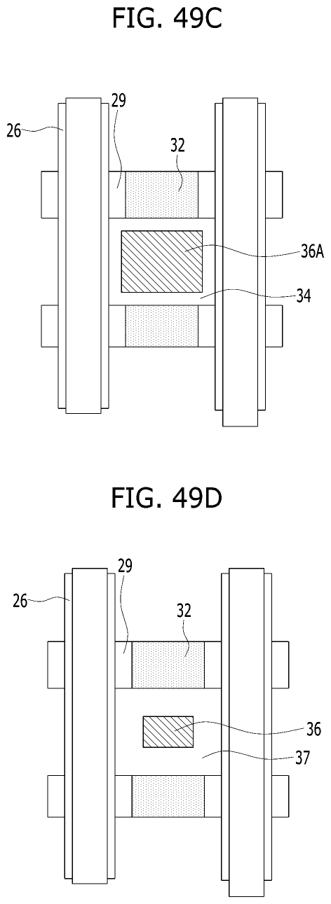

FIGS. 49A to 49D are plan views illustrating a method of forming a storage node contact plug in detail.

Referring to FIGS. 15 and 49A, the plug isolation layer 32A and the initial contact openings 33A may be formed.

Referring to FIGS. 16 and 49B, a trimming process of the sacrificial spacer 29 and the plug isolation layer 32 may be performed.

Referring to FIGS. 20 and 49C, a metallic sacrificial spacer 34 and a lower plug 36A may be formed.

Referring to FIGS. 23 and 49D, after the metallic sacrificial spacer 34 is removed, the second spacer layer 37 and the trimmed lower plug 36 may be formed.

According to the above-described embodiments, spaces of the contact openings 33 may be additionally secured so that the open margin of the contact openings 33 may be secured.

Also, since the size of the storage node contact plug facing the bit line 23, that is, the size of the lower plug 36 is reduced and the structure of the bit line spacer BLS is changed into an N-O structure, the bit line parasitic capacitance may be reduced.

Also, since the upper plug 38 of the storage node contact plug has a larger width than the lower plug 36, the contact resistance may be improved by increasing the contact area with the subsequent landing pad 40.

Also, it may be possible to secure the area of the contact openings 33 by performing an anisotropic etching process using dry etching, regardless of the type of the plug isolation layer 32.

According to the embodiment of the present invention, since the thickness of silicon nitride occupying a bit line spacer is reduced, it is possible to suppress an increase in parasitic capacitance.

According to the embodiment of the present invention, the parasitic capacitance between a bit line and a storage node contact plug may be reduced.

According to the embodiment of the present invention, since an additional space for a storage node contact hole is secured, an open margin of the storage node contact hole may be secured.

According to the embodiment of the present invention, since the size of the storage node contact plug facing a bit line is reduced and the structure of the bit line spacer is changed to a nitride-oxide (N-O) structure, the parasitic capacitance between the bit line and the storage node contact plug may be reduced.

According to the embodiment of the present invention, since the upper plug of the storage node contact plug has a greater width than the lower plug, contact resistance may be improved by increasing the contact area with a landing pad, which will be formed subsequent.

According to the embodiment of the present invention, it is possible to secure the area for contact openings by performing an anisotropic etching process using dry etching, regardless of the type of a plug isolation layer.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a plurality of bit line structures formed to be spaced apart from each other over a semiconductor substrate;
a first spacer formed on both sidewalls of each of the bit line structures;
a lower plug formed between the bit line structures and in contact with the semiconductor substrate;
an upper plug positioned over the lower plug and having a greater line width than the lower plug;
a middle plug positioned between the lower plug and the upper plug and having a smaller line width than a line width of the lower plug; and
a second spacer positioned between the middle plug and the first spacer, wherein the second spacer is thicker than the first spacer.

2. The semiconductor device of claim 1, wherein the lower plug, the middle plug, and the upper plug include the same material.

3. The semiconductor device of claim 1, wherein the lower plug, the middle plug, and the upper plug include polysilicon.

4. The semiconductor device of claim 1, wherein the first spacer includes silicon nitride, and the second spacer includes silicon oxide.

5. The semiconductor device of claim 1, wherein the first spacer has a line shape which is parallel to both sidewalls of each of the bit line structure.

6. The semiconductor device of claim 1, wherein the second spacer has a shape surrounding a sidewall of the lower plug.

7. The semiconductor device of claim 1, further comprising:
a landing pad over the upper plug;
an ohmic contact layer between the landing pad and the upper plug; and
a capacitor over the landing pad.

8. The semiconductor device of claim 7, wherein the landing pad has a shape extending to overlap with an upper surface of the bit line structure.

9. The semiconductor device of claim 1, wherein the bit line structure includes:
a bit line contact plug coupled to the semiconductor substrate;
a bit line over the bit line contact plug; and
a bit line hard mask over the bit line.

10. The semiconductor device of claim 9, wherein a portion of the first spacer extends from both sidewalls of the bit line contact plug,
the semiconductor device further comprising:
a gap-fill spacer positioned over the extending first spacer.

11. The semiconductor device of claim 1, wherein the lower plug includes:
a wide plug contacting the semiconductor substrate; and
a narrow plug positioned over the wide plug and having a smaller line width than the wide plug.

12. A method for fabricating a semiconductor device, comprising:
forming a plurality of bit line structures over a semiconductor substrate;
forming a first spacer on both sidewalls of each of the bit line structures;
forming plug isolation layers and initial contact openings that are positioned between the bit line structures over the first spacer;
trimming the plug isolation layers and the initial contact openings to form contact openings which are wider than the initial contact openings;
forming sacrificial spacers surrounding sidewalls of the contact openings;
forming lower plugs partially filling the contact openings;
removing the sacrificial spacers to form air gaps surrounding the lower plugs; and
forming second spacers to fill the air gaps while surrounding the lower plugs.

13. The method of claim 12, wherein the forming of the second spacers includes:
selectively oxidizing exposed surfaces of the lower plugs.

14. The method of claim 12, wherein the forming of the second spacers includes:
forming a first oxide over exposed surfaces of the lower plugs; and
forming a second oxide filling the air gaps over the first oxide.

15. The method of claim 12, wherein the second spacer is formed to be thicker than the first spacer.

16. The method of claim 12, wherein the first spacer includes silicon nitride, and the second spacer includes silicon oxide.

17. The method of claim 12, further comprising:
forming upper plugs having a greater line width than the lower plugs over the lower plugs, after the forming of the second spacers.

18. The method of claim 17, wherein the lower plugs and the upper plugs include polysilicon.

19. The method of claim 12, further comprising:
after the forming of the second spacers,
forming upper plugs having a greater line width than the lower plugs over the lower plugs;
forming a landing pad over the upper plugs; and
forming a capacitor over the landing pad.

20. The method of claim 19, wherein the lower plugs and the upper plugs include polysilicon, and the landing pad includes a metal material.

21. The method of claim 12, wherein the sacrificial spacer includes titanium nitride.

22. A method for fabricating a semiconductor device, comprising:
forming a plurality of bit line structures over a semiconductor substrate;
forming a first spacer on both sidewalls of each of the bit line structures;
forming a sacrificial spacer over the first spacer;
forming plug isolation layers and initial contact openings that are positioned between the bit line structures over the sacrificial spacer;
forming lower plugs partially filling the initial contact openings;
trimming the sacrificial spacer and the plug isolation layers to form contact openings which are wider than the initial contact openings;
forming a second spacer that surrounds sidewalls of the contact openings and is thicker than the first spacer; and
forming upper plugs having a greater line width than the lower plugs over the second spacer and the lower plugs.

23. The method of claim 22, wherein the sacrificial spacer includes titanium nitride.

24. The method of claim 22, wherein the lower plugs and the upper plugs include polysilicon.

25. The method of claim 22, wherein the first spacer includes silicon nitride, and the second spacer includes silicon oxide.

26. A method for fabricating a semiconductor device, comprising:
forming a plurality of bit line structures over a semiconductor substrate;
forming a first spacer on both sidewalls of each of the bit line structures;
forming a sacrificial spacer over the first spacer;
forming plug isolation layers and initial contact openings positioned between the bit line structures over the sacrificial spacer;
trimming the sacrificial spacer and the plug isolation layers to form contact openings which are wider than the initial contact openings;
forming lower plugs partially filling the initial contact openings;
removing the sacrificial spacer to form an air gap surrounding sidewalls of the lower plugs;
forming a second spacer that fills the air gap and is thicker than the first spacer; and
forming upper plugs having a greater line width than the lower plugs over the second spacer and the lower plugs.

27. A method for fabricating a semiconductor device, comprising:
forming a plurality of bit line structures over a semiconductor substrate;
forming a first spacer on both sidewalls of each of the bit line structures;
forming a first sacrificial spacer over the first spacer;
forming plug isolation layers and initial contact openings positioned between the bit line structures over the first sacrificial spacer;
trimming the plug isolation layers to form contact openings which are wider than the initial contact openings;
forming wide plugs partially filling the initial contact openings;
forming a second sacrificial spacer over the wide plugs;
forming narrow plugs having a smaller line width than the wide plugs over the wide plugs exposed by the second sacrificial spacer;
removing the first and second sacrificial spacers to form an air gap surrounding sidewalls of the narrow plugs;
forming a second spacer that fills the air gap and is thicker than the first spacer; and
forming upper plugs having a greater line width than the narrow plugs over the second spacer and the narrow plugs.
